(19) United States
(12) Patent Application Publication
(10) Pub. No.: US 2025/0204197 A1
(43) Pub. Date: Jun. 19, 2025

(54) DISPLAY DEVICE

(71) Applicant: SAMSUNG DISPLAY CO., LTD., YONGIN-SI (KR)

(72) Inventor: JA EUN LEE, Yongin-si (KR)

(21) Appl. No.: 18/921,276

(22) Filed: Oct. 21, 2024

(30) Foreign Application Priority Data
Dec. 14, 2023 (KR) 10-2023-0182263

(51) Int. Cl. H10K 59/40; H10K 59/122; H10K 59/131

(52) U.S. Cl. CPC H10K 59/40; H10K 59/122; H10K 59/131

(57) ABSTRACT

The display device includes a base layer, a pixel defining layer disposed on the base layer, a plurality of pixels that include first color light emitting elements, second color light emitting elements, and third color light emitting elements, and a sensor disposed on the pixel defining layer and spaced apart from the light emitting openings. The sensor includes first line parts that extend in the second direction and pass between the first to third color light emitting elements, and second line parts that extend in the first direction and pass between two adjacent first color light emitting elements and connect two adjacent first line parts to each other. A first end and a second end of each of the second line parts are in contact with the adjacent first line parts, respectively.

### CROSS-REFERENCE TO RELATED APPLICATIONS

This U.S. non-provisional patent application claims priority under 35 U.S.C. § 119 from Korean Patent Application No. 10-2023-0182263, filed on Dec. 14, 2023 in the Korean Intellectual Property Office, the contents of which are herein incorporated by reference in their entirety.

### TECHNICAL FIELD

Embodiments of the present disclosure herein are directed to a display device, and more particularly, to a display device that includes an input sensor.

### DISCUSSION OF THE RELATED ART

Multimedia electronic devices such as televisions, mobile phones, tablets, navigation, game consoles, etc., display images to users through display screens and provide a touch-based input method that allows users to input information or commands intuitively and conveniently. Such an electronic device includes a display panel that generates an image and an input sensor that detects a user's touch.

The input sensor that detects a user's touch includes a conductive layer that transmits a signal, and the conductive layer includes signal patterns and connection patterns. An arrangement of the signal patterns and connection patterns that transmit signals can be adjusted to ensure reliability of signal transmission. Light emitting elements may be partially curved depending on a direction in which the user looks according to the arrangement of the signal patterns and connection patterns.

### SUMMARY

Embodiments of the present disclosure provide a display device that includes a display panel with increased display quality.

An embodiment of the inventive concept provides a display device that includes: a base layer; a pixel defining layer disposed on the base layer and that includes a plurality of light emitting openings spaced apart from each other; a plurality of pixels that include a plurality of first color light emitting elements, a plurality of second color light emitting elements, and a plurality of third color light emitting elements and disposed in the light emitting openings, where the first to third colors differ from each other; and a sensor disposed on the pixel defining layer and spaced apart from the light emitting openings. The sensor includes: a plurality of first line parts that extend in a second direction and pass between the first to third color light emitting elements; and a plurality of second line parts that extend in a first direction that crosses the second direction and pass between two adjacent first color light emitting elements of the plurality of first color light emitting elements and connect two adjacent first line parts of the plurality of first line parts to each other. A first end and a second end of each of the second line parts are in contact with the adjacent first line parts, respectively.

In an embodiment, the sensor includes a plurality of third line parts that extend in the first direction and pass between two adjacent light emitting elements of the plurality of second color light emitting elements and the plurality of third color light emitting elements and connect two adjacent first line parts of the plurality of first line parts to each other.

In an embodiment, areas between the first color light emitting elements include: a first area on which one of the second line parts is disposed; and a second area that does not overlap the second line parts.

In an embodiment, the second line parts and the first color light emitting elements are alternately arranged in the second direction.

In an embodiment, the first color light emitting elements and the second color light emitting elements are alternately arranged in the second direction, and a number of light emitting elements between the adjacent third line parts is an odd number.

In an embodiment, the number of light emitting elements between adjacent third line parts is three.

In an embodiment, some light emitting elements of the plurality of second color light emitting elements and the plurality of third color light emitting elements between the adjacent third line parts of the plurality of third line parts include one more than a number of other light emitting elements.

In an embodiment, the plurality of light emitting openings comprise a plurality of first light emitting openings, a plurality of second light emitting openings respectively spaced apart from the first light emitting openings in the first direction, and a plurality of third light emitting openings respectively spaced apart from the first light emitting openings in the first direction and respectively spaced apart from the second light emitting openings in the second direction. The plurality of first color light emitting elements are respectively disposed in the first light emitting openings, the plurality of second color light emitting elements are respectively disposed in the second light emitting openings, and the plurality of third color light emitting elements are respectively disposed in the third light emitting openings. A first distance between the first light emitting openings adjacent in the second direction may be greater than a second distance between each of the second light emitting openings and each of the third light emitting openings that are adjacent in the second direction, and a width of each of the second line parts is greater than or equal to that of each of third line parts.

In an embodiment, some portions of the third line parts overlap the second line part in the first direction, and remaining portions of the first line parts do not overlap the second line part in the first direction.

In an embodiment, the display device further includes an encapsulation layer disposed on the pixel defining layer and that covers the first to third color light emitting elements. The sensor includes: a first insulating layer disposed on the encapsulation layer; a first conductive layer disposed on the first insulating layer; a second insulating layer disposed on the first conductive layer; a second conductive layer disposed on the second insulating layer, wherein the first line parts and the second line parts may be disposed on the first conductive layer or the second conductive layer.

In an embodiment of the inventive concept, a display device includes: first pixel columns and second pixel columns that are arranged in a first direction and include a plurality of pixels arranged in a second direction that crosses the first direction; and a sensor disposed between the pixels. Each of the pixels includes: a first color light emitting element; a second color light emitting element spaced apart from the first color light emitting element in the first direction; and a third color light emitting element spaced apart from the first color light emitting element in the first direction and spaced apart from the second color light emitting element in the second direction. The sensor includes: a plurality of first line parts that extend in the second direction and pass between the first to third color light emitting elements; and a plurality of second line parts that extend in the first direction and connect two adjacent first line parts of the plurality of first line parts to each other. The second line parts are disposed between the adjacent first color light emitting elements in the second direction.

In an embodiment, the second line parts include: first sub-line parts disposed between the first pixel columns; and second sub-line parts disposed between the second pixel columns. The first sub-line parts and the second sub-line parts overlap each other in the first direction.

In an embodiment, areas between the first color light emitting elements include: a first area on which one of the plurality of second line parts is disposed; and a second area that does not overlap the second line parts.

In an embodiment, the second line parts and the plurality of first color light emitting elements are alternately arranged in the second direction.

In an embodiment, the sensor includes a plurality of third line parts that extend in the first direction and pass between two adjacent light emitting elements of the plurality of second color light emitting elements and the plurality of third color light emitting elements and connect two adjacent first line parts of the plurality of first line parts to each other.

In an embodiment, a number of the plurality of second color light emitting elements and a number of the plurality of third color light emitting elements adjacent in one direction in each of the third line parts within each of the first pixel columns or the second pixel columns are the same.

In an embodiment, the plurality of first color light emitting elements and the plurality of second color light emitting elements are alternately arranged in the second direction, a number of light emitting elements between the adjacent third line parts of the plurality of third line parts is an odd number, and some light emitting elements of the plurality of second color light emitting elements and the plurality of third color light emitting elements between the adjacent third line parts include one more than a number of other light emitting elements.

In an embodiment, some portions of the third line parts overlap the second line part in the first direction, and remaining portions of the first line parts do not overlap the second line part in the first direction.

In an embodiment, the second line parts include: first sub-line parts disposed between the first pixel columns; and second sub-line parts disposed between the second pixel columns, and the third line parts include: third sub-line parts disposed between the first pixel columns; and fourth sub-line parts disposed between the second pixel columns. The first sub-line parts and the second sub-line parts overlap each other in the first direction, and the third sub-line parts and the fourth sub-line parts overlap each other in the first direction.

In an embodiment, a width of each of the second line parts is greater than or equal to that of each of the third line parts.

### BRIEF DESCRIPTION OF THE FIGURES

FIG. 1 is a perspective view of a display device according to an embodiment of the inventive concept.

FIG. 2 is an exploded perspective view of a display device according to an embodiment of the inventive concept.

FIG. 3 is an enlarged cross-sectional view of a display device according to an embodiment of the inventive concept.

FIG. 4 is a cross-sectional view of a display module according to an embodiment of the inventive concept.

FIG. 5 is a plan view of a display panel according to an embodiment of the inventive concept.

FIG. 6 is a plan view of an input sensor according to an embodiment of the inventive concept.

FIG. 7 is a cross-sectional view of a display module according to an embodiment of the inventive concept.

FIG. 8 is a plan view of a display module according to an embodiment of the inventive concept.

FIG. 9 illustrates how a portion of a pixel is curved by a sensor line according to a direction in which a user looks.

FIG. 10 is a plan view of a display module according to an embodiment of the inventive concept.

FIG. 11 is a plan view of a display module according to an embodiment of the inventive concept.

FIG. 12 is a plan view of a display module according to an embodiment of the inventive concept.

FIG. 13 is a plan view of a display module according to an embodiment of the inventive concept.

FIG. 14 is a plan view of a display module according to an embodiment of the inventive concept.

FIG. 15 is a plan view of a display module according to an embodiment of the inventive concept.

### DETAILED DESCRIPTION

In this specification, it will also be understood that when one component (or area, layer, portion) is referred to as being ‘on’, ‘connected to’, or ‘coupled to’ another component, it can be directly disposed/connected/coupled on/to the one component, or an intervening third component may also be present.

Like reference numerals may refer to like elements throughout.

Hereinafter, a display panel and a method for manufacturing the same according to an embodiment of the inventive concept will be described with reference to the accompanying drawings.

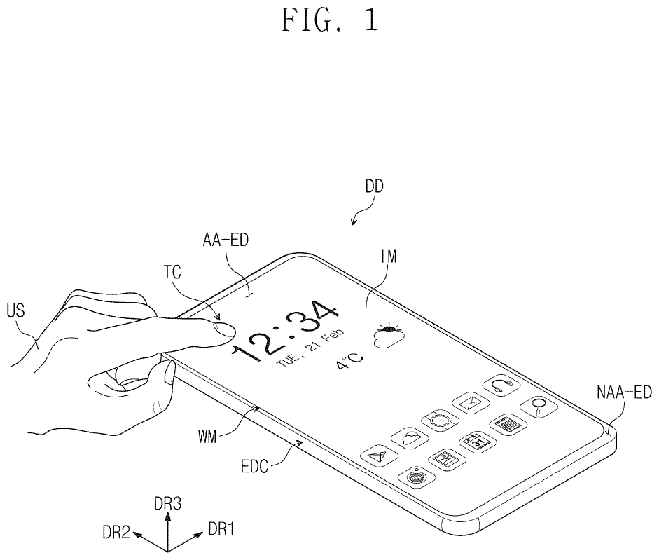

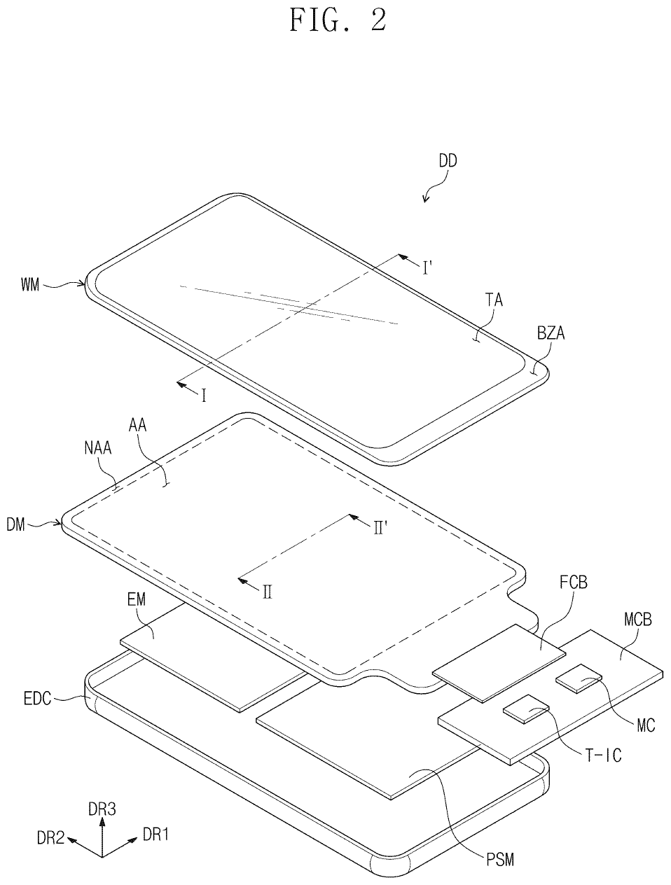

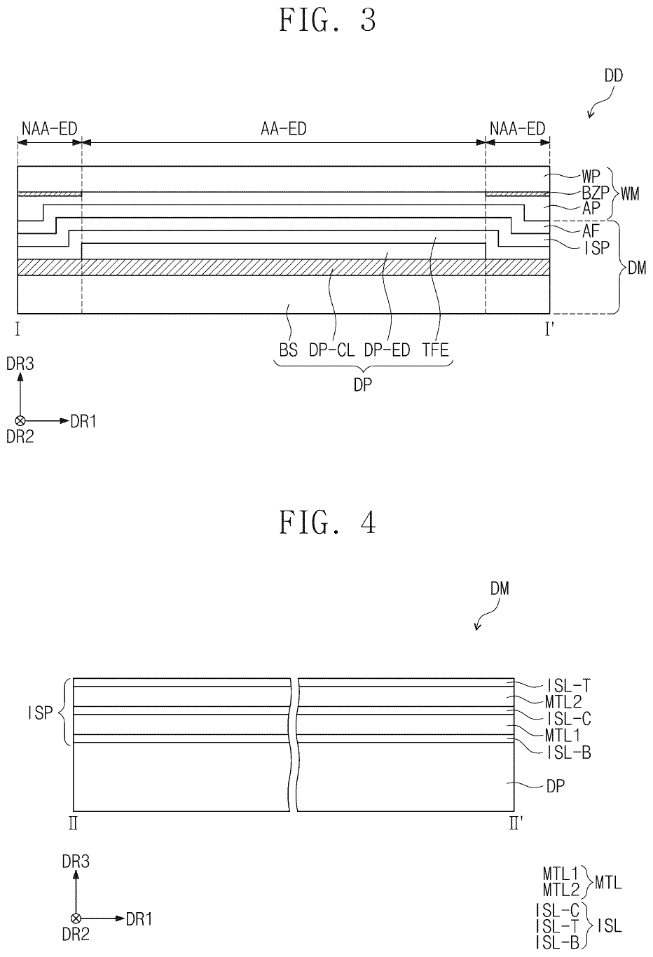

FIG. 1 is a perspective view of a display device according to an embodiment of the inventive concept, FIG. 2 is an exploded perspective view of a display device according to an embodiment of the inventive concept, and FIG. 3 is an enlarged cross-sectional view of a display device according to an embodiment of the inventive concept. FIG. 3 is a cross-sectional view taken along line I-I′ of FIG. 2.

Referring to FIG. 1, in an embodiment, a display device DD can be activated according to an electrical signal to display an image. For example, the display device DD may be a large-sized device such as a television, an external billboard, etc., or a small and medium-sized device such as a monitor, a mobile phone, a tablet PC, a navigation system, a game console, etc. However, embodiments of the display device DD are merely examples and are not necessarily limited thereto unless departing from the concept of the present disclosure.

The display device DD may be rigid or flexible. “Flexible” refers to a property of being able to be bent. For example, the flexible display device DD may be a curved device, a rollable device, or a foldable device.

The first to third directional axes DR1 to DR3 are illustrated in FIG. 1 and following drawings, and directions indicated by the first to third directional axes DR1, DR2, and DR3, which are described in this specification, are relative concepts and thus can be changed into different directions. In addition, directions indicated by the first to third direction axes DR1, DR2, and DR3 may be described as first to third directions DR1, DR2, and DR3, and the same reference numerals may be used. In this specification, the first directional axis DR1 and the second directional axis DR2 are perpendicular to each other, and the third directional axis DR3 is normal with respect to the plane defined by the first directional axis DR1 and the second directional axis DR2.

A thickness direction of the display device DD is a direction parallel to the third directional axis DR3. In this specification, a front surface (or top surface) and a rear surface (or bottom surface) of each member of the display device DD may be defined based on the third directional axis DR3. A front surface (or top surface) and a rear surface (or bottom surface) of each member of the display device DD are opposed to each other in the third direction DR3, and a normal direction of each of the front and rear surfaces is substantially parallel to the third direction DR3. A spaced distance between the front surface and the rear surface defined along the third direction DR3 corresponds to a thickness of a member.

In this specification, the term “in a plan view” refers to a state of being viewed in the third direction DR3. In this specification, “in a cross-sectional view” refers to a state of being viewed from the first direction DR1 or the second direction DR2. The directions indicated as the first to third directions DR1, DR2, and DR3 are relative concepts and thus can be changed into different directions.

The display device DD according to an embodiment displays an image IM through an active area AA-ED. The active area AA-ED is parallel to a plane defined by the first direction DR1 and the second direction DR2. The active area AA-ED further includes a curved surface that is bent from at least one side of the plane defined by the first and second directions DR1 and DR2. The surface on which the image IM is displayed corresponds to a front surface of the display device DD. The image IM may be a still image or a dynamic image.

A peripheral area NAA-ED is adjacent to the active area AA-ED. The peripheral area NAA-ED surrounds the active area AA-ED. Thus, a shape of the active area AA-ED is substantially defined by the peripheral area NAA-ED. However, this is an example, and embodiments are not necessarily limited thereto. For example, in some embodiments, the peripheral area NAA-ED is adjacent to only one side of the active area AA or is omitted. The active area of the display device DD according to an embodiment of the inventive concept may have various shapes, but is not necessarily limited to a specific embodiment.

The display device DD that is unfolded has a rectangular planar shape that has short sides extending in a first direction DR1 and long sides extending in a second direction DR2 that cross the first direction DR1. However, embodiments of the inventive concept are not necessarily limited thereto, and the display device DD may have various other planar shapes, such as a circular shape or a polygonal shape.

The display device DD can sense an externally applied input TC. The external input TC may be one of various types of inputs, such as a force, a pressure, a temperature, and/or light. In an embodiment, FIG. 1 illustrates an external touch input TC by a user's hand US applied to the front surface of the display device DD as an example. However, embodiments are not necessarily limited thereto, and the external input TC may include any input that is capable of changing capacitance of the input sensor. An area of the display device DD that detects the external input TC is not limited to the front surface of the display device DD, and the display device DD can detect the external input TC of the user US that is applied to the side or rear surface of the display device DD.

Referring to FIGS. 1 to 3, the display device DD according to an embodiment includes a display module DM. The display Module DM generates an image and senses an externally applied input. The display module DM according to an embodiment includes a display panel DP and an input sensor ISP disposed on the display panel DP. In addition, the display module DM according to an embodiment further includes an optical layer AF disposed on the input sensor ISP.

The display device DD according to an embodiment includes a window module WM disposed on the display module DM. In addition, the display device DD further includes an electronic module EM, a power supply module PSM, and a housing EDC.

The display module DM according to an embodiment includes an active area AA and a peripheral area NAA. The active area AA is activated according to an electrical signal. The peripheral area NAA is disposed adjacent to at least one side of the active area AA.

The active area AA corresponds to the active area AA-ED of the electronic device illustrated in FIG. 1. The peripheral area NAA surrounds the active area AA, and corresponds to the peripheral area NAA-ED of FIG. 1. However, embodiments of the inventive concept are not necessarily limited thereto, and unlike an example illustrated in FIG. 2, a portion of the peripheral area NAA according to an embodiment may be omitted.

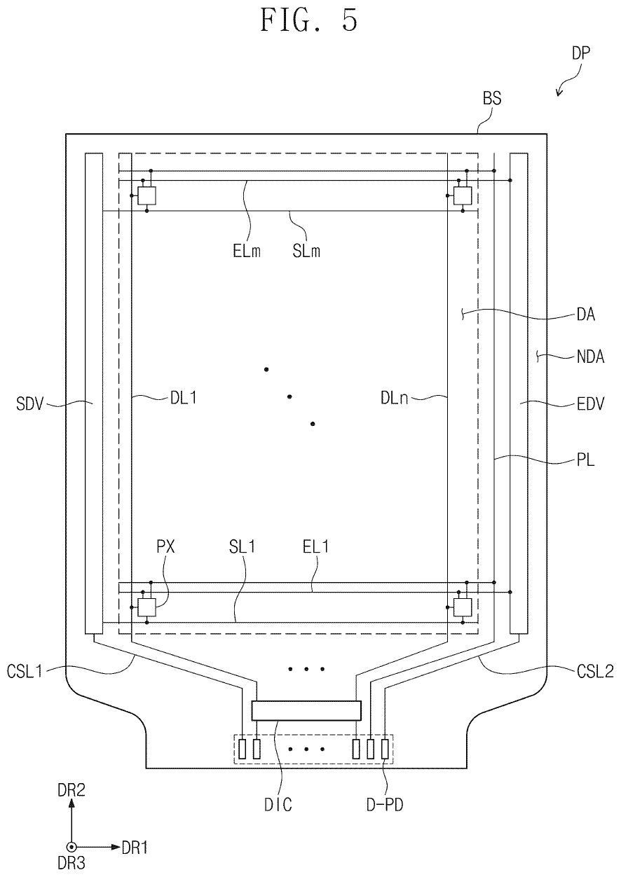

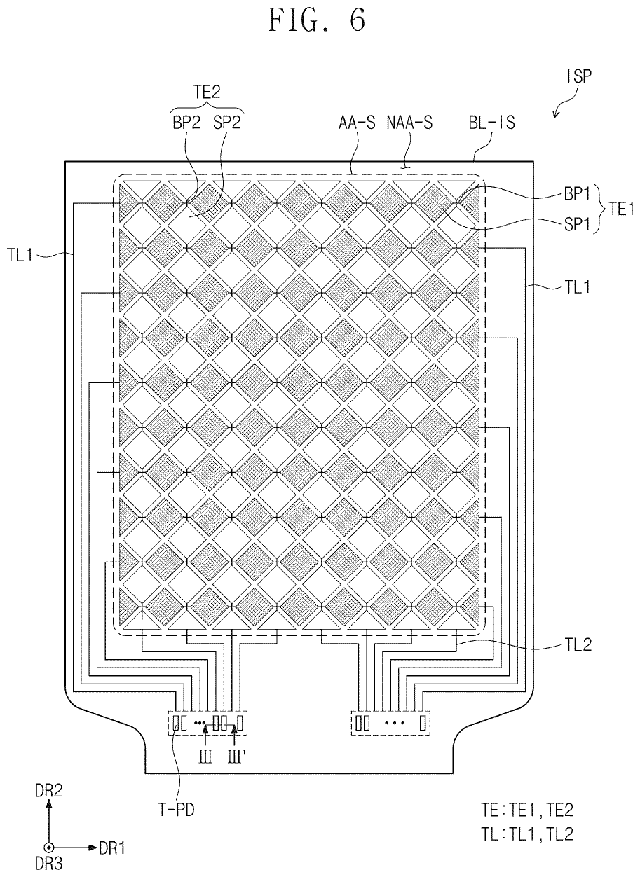

The display module DM according to an embodiment includes a peripheral area NAA disposed on at least one side of the active area AA, and an area on which pads (D-PD of FIG. 5 and T-PF of FIG. 6) are disposed on the peripheral area NAA is referred to as a pad area. The pad area is a portion of the peripheral area NAA. A driving circuit or a driving line that drives the active area AA is disposed on the pad area.

The window module WM is disposed on the display module DM and protects the display module DM from external impacts or scratches. The window module WM covers the entire outside of the display module DM. A front surface of the window module WM corresponds to a top surface of the display device DD described above.

In an embodiment, the window module WM includes a base material WP that includes an optically transparent insulating material. The base material WP includes at least one of a glass base material or a synthetic resin film. The base material WP may have a single-layer structure or a multi-layer structure in which a plurality of films are coupled to each other. The window module WM may further include a functional layer such as an anti-fingerprint layer, a phase control layer, or a hard coating layer that is disposed on the base material WP.

The window module WM further includes an adhesive layer AP. The base material WP and the display module DM are coupled to each other through the adhesive layer AP. However, embodiments of the inventive concept are not necessarily limited thereto, and in some embodiments, the adhesive layer AP is omitted, and the window module WM is disposed directly on the display module DM.

The window module WM includes a transmission part TA and a bezel part BZA. The transmission area TA corresponds to the active area AA of the display module DM, and the bezel area BZA corresponds to the peripheral area NAA of the display module DM. The bezel part BZA defines a shape of the transmission part TA. The bezel part BZA is adjacent to the transmission part TA and surrounds the transmission part TA. However, embodiments of the inventive concept are not necessarily limited thereto. For example, in some embodiments, the bezel part BZA is disposed adjacent to only one side of the transmission part TA, and a portion of the bezel part BZA is omitted.

The window module WM further includes a bezel pattern BZP disposed in the bezel part BZA. The bezel pattern BZP is a color layer disposed on one surface of the base material WP. The bezel pattern BZP includes a colored material. For example, the bezel pattern BZP includes a colored organic film. The bezel pattern BZP may have a single-layer or multi-layer structure. The bezel part BZA of the window module WM on which the bezel pattern BZP is disposed has a light transmittance that is less than that of the transmission part TA.

The display module DM further includes a main circuit board MCB, a flexible circuit film FCB, a data driver DIC (see FIG. 5), a sensor control circuit T-IC, and a main controller MC.

The main circuit board MCB is electrically connected to the display module DM through the flexible circuit film FCB. The main circuit board MCB is electrically connected to the electronic module EM through a connector.

The flexible circuit film FCB is connected to each of the display panel DP and the input sensor ISP and electrically connects the display panel DP and the input sensor ISP to the main circuit board MCB. The input sensor ISP is electrically connected to the display panel DP and is electrically connected to the main circuit board MCB through the flexible circuit film FCB. However, embodiments are not necessarily limited thereto, and in some embodiments, the input sensor ISP is electrically connected to the main circuit board MCB through an additional flexible circuit film, or the flexible circuit film FCB is omitted, and the main circuit board MCB is directly connected to the display panel DP.

Each of the data driver DIC (see FIG. 5), the sensor control circuit T-IC, and the main controller MC is provided in the form of an integrated chip. The data driver DIC (see FIG. 5) is mounted on the display module DM, and the sensor control circuit T-IC and main controller MC are mounted on the main circuit board MCB. However, embodiments of the inventive concept are not necessarily limited thereto. For example, in some embodiments, the data driver DIC (see FIG. 5) is mounted on the flexible circuit film FCB.

The main controller MC controls an overall operation of the display device DD. For example, the main controller MC controls operations of the display panel DP and the input sensor ISP. In addition, the main controller MC controls an operation of the electronic module EM. The main controller MC includes at least one microprocessor.

The data driver DIC (see FIG. 5) includes a driving circuit that drives pixels of the display panel DP. The data driver DIC (see FIG. 5) receives image data and a control signal from the main controller MC. For example, the control signal includes an input vertical synchronization signal, an input horizontal synchronization signal, a main clock, and a data enable signal.

The sensor control circuit T-IC provides an electrical signal to the input sensor ISP that drives the input sensor ISP. The sensor control circuit T-IC receives control signals, such as a clock signal, from the main controller MC.

The electronic module EM includes various functional modules that drive the display device DD. For example, the electronic module EM includes a wireless communication module, an image input module, an audio input module, an audio output module, a memory, and an external interface module. The modules of the electronic module EM may be mounted on the main circuit board MCB or may be electrically connected to the main circuit board MCB through a separate flexible circuit board.

The power supply module PSM is electrically connected to the electronic module EM. The power supply module PSM supplies power for an overall operation of the display device DD. For example, the power supply module PSM includes a typical battery device.

The window module WM and the housing EDC are coupled to each other and configure an outer appearance of the display device DD. The coupled window module WM and housing EDC define an internal space that accommodates components of the display device DD. The internal space accommodates the display module DM, the flexible circuit film FCB, the main circuit board MCB, the electronic module EM, and the power supply module PSM. A portion of the display module DM can be bent so that the flexible circuit film FCB and the main circuit board MCB face a rear surface of the display module DM and are accommodated in the housing EDC.

The housing EDC includes a relatively rigid material. For example, the housing EDC includes at least one of glass, plastic, or a metal, or includes a plurality of frames and/or plates made of a combination of glass, plastic, and a metal. The housing EDC protects the display module DM in the housing EDC by absorbing externally applied impacts and prevents foreign substances/moisture from permeating from the outside.

In the display device DD according to an embodiment, the display panel DP generates an image. The display panel DP may be an emission type display panel. For example, the display panel DP is one of an organic light emitting display panel, an inorganic light emitting display panel, a quantum dot display panel, a micro LED display panel, or a nano LED display panel. The display panel DP may be referred to as a display layer.

Referring to FIG. 3, the display panel DP includes a base layer BS, a circuit layer DP-CL, a display element layer DP-ED, and a film encapsulation layer TFE.

The base layer BS provides a base surface on which the circuit layer DP-CL is disposed. The base layer BS may be a rigid substrate or a flexible substrate that can be bent, folded, or rolled. The base layer BS may be a glass substrate, a metal substrate, or a polymer substrate. However, embodiments of the inventive concept are not necessarily limited thereto. For example, in some embodiments, the base layer BS is one of an inorganic layer, an organic layer, or a composite layer.

In an embodiment, the base layer BS has a multilayered structure. For example, the base layer BS includes a first synthetic resin layer, an intermediate layer that may have multiple layer or a single-layer structure, and a second synthetic resin layer disposed on the intermediate layer. The intermediate layer may be referred to as a base barrier layer. The intermediate layer includes, but is not particularly limited to, a silicon oxide (SiOx) layer and an amorphous silicon (a-Si) layer disposed on the silicon oxide layer. For example, the intermediate layer includes at least one of a silicon oxide layer, a silicon nitride layer, a silicon oxy nitride layer, or an amorphous silicon layer.

Each of the first and second synthetic resin layers includes a polyimide-based resin. In addition, each of the first and second synthetic resin layers includes at least one of an acrylate-based resin, a methacrylate-based resin, a polyisoprene-based resin, a vinyl-based resin, an epoxy-based resin, an urethane-based resin, a cellulose-based resin, a siloxane-based resin, a polyamide-based resin, or a perylene-based resin. In this specification, the “˜˜”-based resin indicates the inclusion of a functional group of “˜˜”.

The circuit layer DP-CL is disposed on the base layer BS. The circuit layer DP-CL includes an insulating layer, a semiconductor pattern, a conductive pattern, and a signal line. The insulating layer, a semiconductor layer, and a conductive layer are formed by a manner such as coating or vapor deposition, and the insulating layer, the semiconductor layer, and the conductive layer are selectively patterned through a plurality of photolithography processes. Thereafter, the semiconductor pattern, the conductive pattern, and the signal line in the circuit layer DP-CL are provided. The circuit layer DP-CL includes an insulating layer and may include a plurality of inorganic insulating layers and a plurality of organic insulating layers.

The display element layer DP-ED is disposed on the circuit layer DP-CL. The display element layer DP-ED includes a light emitting element. For example, the display element layer DP-ED includes at least one of an organic light emitting material, an inorganic light emitting material, an organic-inorganic light emitting material, a quantum dot, a quantum rod, a micro LED, or a nano LED. The light emitting elements of the display element layer DP-ED are electrically connected to the driving elements of the circuit layer DP-CL and display images by generating light according to signals provided by the driving elements.

The encapsulation layer TFE is disposed on the display element layer DP-ED. The encapsulation layer TFE protects the display element layer DP-ED from foreign substances such as moisture, oxygen, and dust particles. The encapsulation layer TFE seals the light emitting elements of the display element layer DP-ED. The encapsulation layer TFE includes at least one thin film that improves optical efficiency of the display element layer DP-ED or protects the display element layer DP-ED.

The input sensor ISP is disposed on the display panel DP. The input sensor ISP can sense the external input TC applied from the outside. The external input TC may be an input of a user. The user's input includes various types of external inputs, such as a portion of a user's body, light, heat, a pen, a pressure, etc. The input sensor ISP detects the external input TC and provides an input signal that includes information about the external input TC so that the display panel DP can generate an image IM that corresponds to the external input TC. The input sensor ISP may be driven in various manners, such as a capacitive manner, a resistive manner, an infrared manner, or a pressure manner, but is not necessarily limited thereto. In an embodiment, the input sensor ISP is driven in a capacitive manner.

The input sensor ISP is disposed on the display panel DP through a continuous process. For example, the input sensor ISP is disposed directly on the display panel DP. The direct disposition mean that no third component is disposed between the input sensor ISP and the display panel DP. For example, no separate adhesive member is disposed between the input sensor ISP and the display panel DP.

The optical layer AF is disposed on the input sensor ISP. The optical layer AF is a reflection reduction layer that reduces reflectance by externally incident light. The optical layer AF is disposed on the input sensor ISP through a continuous process. For example, the optical layer AF includes a polarizing film that includes a phase retarder and/or a polarizer, multi-layered reflective layers that destructively interfere reflected light, or color filters that correspond to the pixel arrangement and emission colors of the display panel DP. For example, when the optical layer AF includes color filters, the color filters are arranged according to the emission colors of the pixels in the display panel DP. However, embodiments are not necessarily limited thereto, In an embodiment, the optical layer AF is omitted.

FIG. 4 is a cross-sectional view of a display module according to an embodiment. FIG. 4 illustrates a portion that corresponds to a line II-II′ of FIG. 2. For example, FIG. 4 is a cross-sectional view that corresponds to a portion of the active area AA (see FIG. 2) of the display module DM.

The display module DM according to an embodiment includes a display panel DP and an input sensor ISP. The input sensor ISP may be referred to as a sensor layer, an input sensing layer, or an input sensing panel. The components described with reference to FIGS. 2 and 3 also apply to the display panel DP.

Referring to FIG. 4, in an embodiment, the input sensor ISP is in contact with the display panel DP. The input sensor ISP is in contact with the top surface of the display panel DP. In an embodiment, the input sensor ISP is in direct contact with the top surface of the display panel DP. The input sensor ISP includes a plurality of sensor insulating layers ISL and a plurality of sensor conductive layers MTL. The plurality of sensor insulating layers ISL include a first sensor insulating layer ISL-B, a second sensor insulating layer ISL-C, and a third sensor insulating layer ISL-T, and the plurality of sensor conductive layers MTL include a first sensor conductive layer MTL1 and a second sensor conductive layer MTL2. For example, in an embodiment, the input sensor ISP includes the first sensor insulating layer ISL-B, the first sensor conductive layer MTL1, the second sensor insulating layer ISL-C, the second sensor conductive layer MTL2, and the third sensor insulating layer ISL-T that are sequentially laminated on the display panel DP in the third direction DR3.

The first sensor insulating layer ISL-B is in direct contact with the top surface of the display panel DP. The first sensor insulating layer ISL-B may include a base insulating layer. In addition, the first sensor insulating layer may include a buffer insulating layer. For example, the input sensor ISP may be a single layer provided as only the base insulating layer or the buffer insulating layer, or may have a laminated structure that includes the buffer insulating layer and the base insulating layer, but is not necessarily limited to any one embodiment.

The first sensor conductive layer MTL1 and the second sensor conductive layer MTL2 have a multilayer structure. In an embodiment, the multi-layered sensor conductive layer is a laminate in which two or more transparent conductive layers and/or metal layers are laminated. For example, the multi-layered sensor conductive layer may be a structure in which a transparent conductive layer and a metal layer are laminated, or a structure in which metal layers that include different metals are laminated.

For example, transparent conductive layers in the first sensor conductive layer MTL1 and the second sensor conductive layer MTL2 include at least one of indium tin oxide (ITO), indium zinc oxide (IZO), zinc oxide (ZnO), or indium tin zinc oxide (ITZO), PEDOT, metal nanowires, or graphene. The metal layer in the first sensor conductive layer MTL1 and the second sensor conductive layer MTL2 includes at least one of molybdenum, silver, titanium, copper, aluminum, or an alloy thereof.

The first sensor conductive layer MTL1 and the second sensor conductive layer MTL2 include sensing electrodes TE (FIG. 6) of the input sensor ISP to be described below, and sensing lines TL (FIG. 6).

The second sensor insulating layer ISL-C is disposed on the first sensor conductive layer MTL1. The third sensor insulating layer ISL-T is disposed on the second sensor conductive layer MTL2. Each of the second sensor insulating layer ISL-C and the third sensor insulating layer ISL-T includes an inorganic film. In addition, each of the second sensor insulating layer ISL-C and the third sensor insulating layer ISL-T further includes an organic film.

Each of the first sensor insulating layer ISL-B, the second sensor insulating layer ISL-C, and the third sensor insulating layer ISL-T include at least one of silicon nitride (SiNX) or silicon oxynitride (SiOXNY). In addition, each of the first sensor insulating layer ISL-B, the second sensor insulating layer ISL-C, and the third sensor insulating layer ISL-T includes silicon oxide (SiOX). Each of the first sensor insulating layer ISL-B, the second sensor insulating layer ISL-C, and the third sensor insulating layer ISL-T includes an inorganic film and includes at least one of aluminum oxide, titanium oxide, zirconium oxide, or hafnium. In the expressions of silicon nitride (SiNX), silicon oxynitride (SiOXNY), and silicon oxide (SiOX), each of reference symbols X and Y may be greater than 0.

When each of the first sensor insulating layer ISL-B, the second sensor insulating layer ISL-C, and the third sensor insulating layer ISL-T includes an organic film, the organic film includes at least one of an acrylic resin, a methacrylic resin, a polyisoprene-based resin, a vinyl-based resin, an epoxy-based resin, a urethane-based resin, a cellulose-based resin, a siloxane-based resin, a polyimide-based resin, a polyamide-based resin, or a perylene-based resin.

Although FIG. 4 illustrates that the input sensor ISP includes the first sensor conductive layer MTL1 and the second sensor conductive layer MTL2 that are laminated, embodiments are not necessarily limited thereto. For example, in an embodiment, the input sensor ISP includes one sensor conductive layer MTL disposed on the first sensor insulating layer ISL-B. For example, in some embodiments, one of the second sensor insulating layer ISL-C or the third sensor insulating layer ISL-T may be omitted.

Although FIG. 4 shows that each of the first sensor conductive layer MTL1 and the second sensor conductive layer MTL2 is one layer that overlaps the entire display panel DP to schematically represent the laminated structure, embodiments are not necessarily limited thereto. In an embodiment, each of the first sensor conductive layer MTL1 and the second sensor conductive layer MTL2 is patterned.

FIG. 5 is a plan view of a display panel according to an embodiment of the inventive concept.

Referring to FIG. 5, in an embodiment, the display panel DP includes the base layer BS, pixels PX, signal lines SL1 to SLm, DL1 to DLn, EL1 to ELm, CSL1, CSL2, and PL that are electrically connected to the pixels PX, a scan driver SDV, an emission driver EDV, a data driver DIC, and panel pads D-PD.

The base layer BS provides a base surface on which elements and lines of the display panel DP are disposed. The base layer BS includes a display area DA and a non-display area NDA. The display area DA where the pixels PX are arranged to display an image. The non-display area NDA is adjacent to the display area DA and is where elements and lines that drive the pixels PX are disposed, and no image is displayed. The display area DA corresponds to the active area AA (see FIG. 2) of the display module DM, and the non-display area NDA corresponds to the peripheral area NAA (see FIG. 2) of the display module DM.

Each of the pixels PX includes a pixel driving circuit that includes transistors, such as a switching transistor, a driving transistor, etc, and a capacitor, and the light emitting element electrically connected to the pixel driving circuit. Each of the pixels PX emits light in response to an electrical signal applied to the pixel PX.

In an embodiment, each of the scan driver SDV, the data driver DIC, and the emission driver EDV is disposed on the non-display area NDA. However, embodiments are not necessarily limited thereto, and in some embodiments, at least one of the scan driver SDV, the data driver DIC, or the emission driver EDV is disposed on the display area DA, which reduces a surface area of the non-display area.

The signal lines SL1 to SLm, DL1 to DLn, EL1 to ELm, CSL1, CSL2, and PL include scan lines SL1 to SLm, data lines DL1 to DLn, emission lines EL1 to ELm, first and second control lines CSL1 and CSL2, and a power line PL. Here, m and n are integers greater than or equal to 1. The pixels PX are connected to a corresponding scan line, data line, and light emission line of the scan lines SL1 to SLm, the data lines DL1 to DLn, and the emission lines ECL1 to ECLm, respectively. More types of signal lines may be provided on the display panel DP according to the configuration of the pixel driving circuit of the pixels PX.

The scan lines SL1 to SLm extend in the first direction DR1 and are electrically connected to the scan driver SDV. The data lines DL1 to DLn extend in the second direction DR2 and are electrically connected to the data driver DIC. The emission lines EL1 to ELm extend in the first direction DR1 and are electrically connected to the emission driver EDV.

The first power line PL1 includes a portion that extends in the first direction DR1 and a portion that extends in the second direction DR2. The portion of the power line PL that extends in the second direction DR2 is disposed on the non-display area NDA. The portion of the power line PL that extends in the first direction DR1 crosses the display area and is electrically connected to the pixels PX and the portion of the power line PL that extends in the second direction DR2. The portion of the power line PL that extends in the second direction DR2 may be disposed on a layer different from the portion that extends in the first direction DR1 and is connected through a contact hole, or may have an integrated shape on the same layer as the portion that extends in the first direction DR1.

The first control line CSL1 is electrically connected to the scan driver SDV. The second control line CSL2 is electrically connected to the emission driver EDV.

The panel pads D-PD are disposed adjacent to a lower end of the non-display area NDA. The panel pads D-PD are disposed closer to the lower end of the display panel DP than the data driver DIC. The panel pads D-PD are spaced apart from each other in the first direction DR1. The panel pads PD are portions to which a circuit substrate that provides signals that control operations of the scan driver SDV, the data driver DIC, and the emission driver EDV of the display panel DP is electrically connected.

The panel pads D-PD may be defined as display pads electrically connected to the pixels PX. Each of the panel pads D-PD is connected to a corresponding signal line of the signal lines SL1 to SLm, EL1 to ELm, DL1 to DLn, CSL1, CSL2, and PL. For example, the power line PL, the first and second control lines CSL1 and CSL2, and the data lines DL1 to DLn are connected to corresponding panel pads D-PD. The data lines DL1 to DLn are connected to the corresponding panel pad D-PD through the data driver DIC.

The scan driver SDV generates scan signals in response to scan control signals. The scan signals are applied to the pixels PX through the scan lines SL1 to SLm. The data driver DIC generates data voltages that correspond to image signals in response to data control signals. The data voltages are provided to the pixels PX through the data lines DL1 to DLn. The emission driver EDV generates emission signals in response to emission control signals. The emission signals are applied to the pixels PX through the emission lines EL1 to ELm.

The pixels PX receive the data voltages in response to the scan signals. The pixels PX emit light that has a luminance that corresponds to the data voltages in response to the emission signals to display an image. An emission time of the pixels PX is controlled by the emission signals. Thus, the display panel DP generates an image on the display area DA through the pixels PX.

FIG. 6 is a plan view of an input sensor according to an embodiment of the inventive concept.

Referring to FIG. 6, in an embodiment, the input sensor ISP includes a sensing area AA-S and a non-sensing area NAA-S adjacent to the sensing area AA-S. The sensing area AA-S corresponds to the active area AA (FIG. 2) of the display module. The sensing area AA-S is where the sensing electrodes TE of the input sensor ISP are disposed to sense the external input TC (FIG. 1). The non-detection area NAA-S corresponds to the peripheral area NAA (FIG. 2) of the display module. The non-sensing area NAA-S is where elements or lines that drive the sensing electrodes TE disposed on the sensing area AA-S are disposed.

The input sensor ISP includes sensing electrodes TE, sensing lines TL, and sensing pads T-PD that are disposed on the first sensor insulating layer ISL-B.

The sensing electrodes TE include first sensing electrodes TE1 and second sensing electrodes TE2 that cross each other on a plane and are electrically insulated from each other. The input sensor ISP acquires information about an external input through a change in mutual capacitance between the first and second sensing electrodes TE1 and TE2.

Each of the first sensing electrodes TE1 extends in the first direction DR1, and the first sensing electrodes TE1 are arranged in the second direction DR2. The first sensing electrodes TE1 are provided in a plurality of rows arranged in the second direction DR2. Although FIG. 6 illustrates 10 first sensing electrodes TE1 arranged in the second direction DR2 as an example, the number of first sensing electrodes TE1 in the input sensor ISP is not necessarily limited thereto.

Each of the second sensing electrodes TE2 extends in the second direction DR2, and the second sensing electrodes TE2 are arranged in the first direction DR1. The second sensing electrodes TE2 are provided in a plurality of columns arranged in the first direction DR1. Although FIG. 6 illustrates 8 second sensing electrodes TE2 arranged in the first direction DR1 as an example, the number of second sensing electrodes TE2 in the input sensor ISP is not necessarily limited thereto.

Each of the first sensing electrodes TE1 includes first sensor patterns SP1 and first connection patterns BP1. The first sensor patterns SP1 extend in the first direction DR1. The first connection patterns BP1 connect those first sensor patterns SP1 adjacent to each other in the first direction DR1. The first connection patterns BP1 are disposed on the same layer as the first sensor patterns SP1 and are integrally formed with the first sensor patterns SP1 and extend from the first sensor patterns SP1. The first sensor patterns SP1 and the first connection patterns BP1 are formed by patterning a same conductive layer through a same process. However, as long as the first connection patterns BP1 electrically connect the first sensor patterns SP1 adjacent to each other in the first direction DR1, embodiments are not necessarily limited thereto.

The second sensing electrode TE2 includes second sensor patterns SP2 and second connection patterns BP2. The second sensor patterns SP2 extend in the second direction DR2. The second connection patterns BP2 connect those second sensor patterns SP2 adjacent to each other in the second direction DR2. The second connection patterns BP2 are disposed on a layer that differs from that on which the second sensor patterns SP2 are disposed and is connected to the corresponding second sensor patterns SP2 through contact holes. The second sensor patterns SP2 that are spaced apart from each other in the second direction DR2 are electrically connected through the second connection patterns BP2. The second connection patterns BP2 may be defined as bridge patterns.

in an embodiment, the first sensor patterns SP1, the first connection patterns BP1, and the second sensor patterns SP2 are disposed on the same layer. The second connection patterns BP2 are disposed on a different layer from the second sensor patterns SP2. For example, in an embodiment, the first sensor patterns SP1, the first connection patterns BP1, and the second sensor patterns SP2 are included in the second sensor conductive layer MTL2 (FIG. 4), and the second connection patterns BP2 are included in the first sensor conductive layer MTL1 (FIG. 4). However, embodiments are not necessarily limited thereto, and in some embodiments, the first sensor patterns SP1, first connection patterns BP1, and second sensor patterns SP2 are included in the first sensor conductive layer MTL1 (FIG. 4), and the second connection patterns BP2 are included in the second sensor conductive layer MTL2 (FIG. 4). In other embodiments, the first sensor patterns SP1, the second sensor patterns SP2, and the second connection patterns BP2 are disposed on the same layer, and the first connection patterns BP1 are disposed on a different layer from the first sensor patterns SP1. In other embodiments, the first sensor patterns SP1 and the first connection patterns BP1 are disposed on the same layer, and the second sensor patterns SP2 and the second connection patterns BP2 are disposed on the same layer that differs from the layer of the first sensor patterns SP1 and the first connection patterns BP1.

The sensing lines TL include first sensing lines TL1 and second sensing lines TL2. The first sensing lines TL1 are respectively connected to the first sensing electrodes TE1. Each of the first sensing lines TL1 is connected to the first sensing electrode TE1 in a corresponding row. The second sensing lines TL2 are respectively connected to the second sensing electrodes TE2. Each of the second sensing lines TL2 is connected to the second sensing electrode TE2 in a corresponding column.

The second sensing lines TL2 are connected to lower ends of the respective second sensing electrodes TE2 adjacent to the sensing pads T-PD. The second sensing lines TL2 extend from a lower end of the corresponding second sensing electrode TE2 on the non-sensing area NAA-S and are connected to the sensing pads T-PD.

As illustrated in FIG. 6, the first sensing lines TL1 are connected to left or right ends of the first sensing electrodes TE1. For example, each of the first sensing lines TL1 connected to the first sensing electrodes TE1 in an odd row is connected to the left end of the corresponding first sensing electrode TE1. Each of the first sensing lines TL1 connected to the first sensing electrodes TE1 in an even row is connected to the right end of the corresponding first sensing electrode TE1. The first sensing lines TL1 extend from the left or right end of the corresponding first sensing electrode TE1 on the non-sensing area NAA-S in the second direction DR2 and are connected to the sensing pads T-PD.

The sensing pads T-PD are disposed on the non-sensing area NAA-S. The sensing pads T-PD are disposed adjacent to the lower end of a sensor base layer BL-IS. In an embodiment, the sensor base layer BL-IS is the first sensor insulating layer ISL-B of FIG. 4. The sensing pads T-PD are electrically connected to the sensing lines TL. The sensing pads T-PD are spaced apart from each other and are respectively connected to the sensing lines TL. The sensing pads T-PD are electrically connected to the circuit board that provides the driving signal. A signal is transmitted to the sensing electrodes TE, or a signal is received from the sensing electrodes TE through the sensing pads T-PD and the sensing lines TL.

In an embodiment, driving signals that drive the first sensing electrodes TE1 and the second sensing electrodes TE2 are applied to the first sensing electrode TE1 and the second sensing electrode TE2 through the second sensing lines TL2. A signal containing information sensed by the first and second sensing electrodes TE1 and TE2 is output through the first sensing lines TL1. However, embodiments of the inventive concept are not necessarily limited thereto.

In an embodiment, the sensing pads T-PD are integrally formed with the correspondingly connected sensing lines TL. However, in an embodiment, unlike that illustrated in FIG. 6, the sensing pads T-PD are separated from the sensing lines TL, and one end of the sensing lines TL corresponds to a sensing pad portion connected to a driving chip on the circuit board, etc.

The sensing pads T-PD and the sensing lines TL are formed from the sensor conductive layer MTL (FIG. 4) of the input sensor. For example, in an embodiment, the sensing pads T-PD and the sensing lines TL are formed in the same process as the first sensor conductive layer MTL1. However, embodiments of the inventive concept are not necessarily limited thereto. In some embodiments, the sensing pads T-PD and the sensing lines TL are formed in the same process as the second sensor conductive layer MTL2, or some of the sensing pads T-PD and the sensing lines TL are formed in the same process as the first sensor conductive layer MTL1, and some of the sensing pads T-PD and the sensing lines TL are formed in the same process as the second sensor conductive layer MTL2, depending on the arranged positions of the sensing electrodes TE.

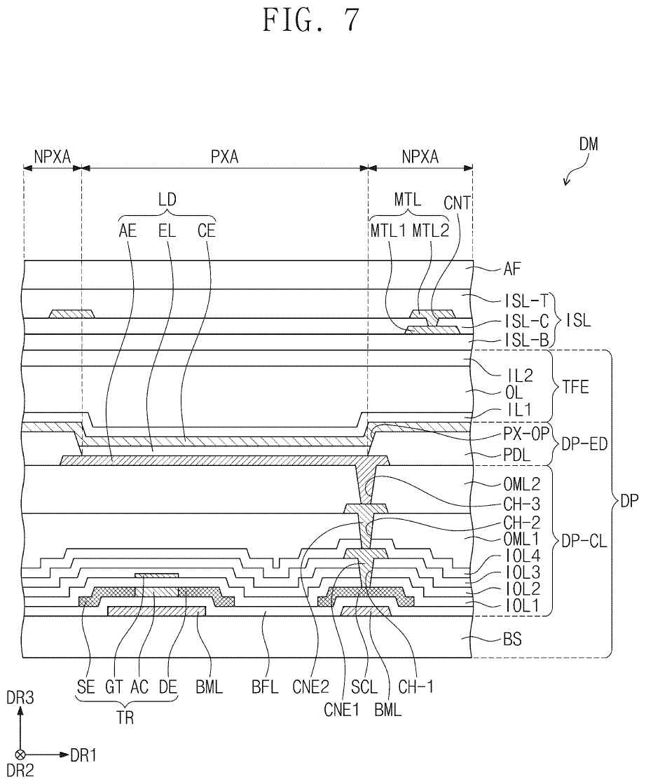

FIG. 7 is a cross-sectional view of a display module according to an embodiment of the inventive concept.

FIG. 7 illustrates a cross section of the display module DM that includes one pixel PX (FIG. 5) illustrated in FIG. 5. The display module DM includes a display panel DP (see FIG. 3) and an input sensor ISP (see FIG. 4), and the display panel DP include the base layer BS, the circuit layer DP-CL, the display element layer DP-ED, and the encapsulation layer TFE. One pixel has an equivalent circuit that includes a plurality of transistors, one capacitor, and a light emitting element, although an equivalent circuit diagram of the pixel can be modified in various forms. FIG. 7 shows one transistor TR and the light emitting element EMD of a pixel as an example.

The display panel DP according to an embodiment includes a plurality of insulating layers, a transistor, a conductive pattern, and a signal line.

A plurality of inorganic films, a plurality of organic films, a semiconductor layer, and a conductive layer are formed by coating, deposition, etc. Thereafter, the inorganic films, the organic films, the semiconductor layer, and the conductive layer are selectively patterned in a photolithography process. The circuit layer DP-CL includes a plurality of insulating layers that are formed from the inorganic films and the organic films, a transistor that includes a semiconductor pattern formed from the semiconductor layer, a conductive pattern formed from the conductive layer, and a signal line formed in the same manner.

Thereafter, the display element layer DP-ED that includes a light emitting element LD that includes the conductive pattern, etc., is disposed on the circuit layer DP-CL, and the encapsulation layer TFE that covers the display element layer DP-ED is disposed on the circuit layer DP-CL.

Referring to FIG. 7, the circuit layer DP-CL includes a shielding electrode BML, a buffer layer BFL, a plurality of insulating layers IOL1, IOL2, IOL3, and IOL4 that include inorganic films, a plurality of insulating layers OML1 and OML2 that include organic films, a transistor TR, connection electrodes CNE1 and CNE2, a signal line SCL, etc.

The shielding electrode BML is disposed on the base layer BS. The shielding electrode BML overlaps the transistor TR. In addition, in an embodiment, the shielding electrode BML is disposed below the signal line SCL. The shielding electrode BML blocks light incident from a lower side of the display panel DP into the transistor TR or the signal line SCL and protects the semiconductor pattern or the conductive pattern, such as the transistor TR and the signal line SCL. The shielding electrode BML includes a conductive material. In an embodiment, the shielding electrode BML is connected to the power line PL (see FIG. 5) to receive a voltage. When the voltage is applied to the shielding electrode BML, a threshold voltage of the transistor TR disposed on the shielding electrode BML can be maintained. In an embodiment, the shielding electrode BML is a floating electrode. In an embodiment, the shielding electrode BML is omitted.

The buffer layer BFL is disposed on the base layer BS and covers the shielding electrode BML. The buffer layer BFL increases a bonding force between the base layer BS and the semiconductor pattern or the conductive pattern disposed on the buffer layer BFL. In addition, the buffer layer BFL prevents metal atoms or impurities from diffusing from the base layer BS into the semiconductor pattern or the conductive pattern.

The buffer layer BFL is an inorganic film. The buffer layer BFL includes at least one of silicon oxide, silicon nitride, or silicon oxynitride. For example, the buffer layer BFL has a structure in which the silicon oxide layer and the silicon nitride layer are alternately laminated.

The transistor TR includes a source SE, a channel AC, a drain DE, and a gate GT. The source SE, the channel AC, and the drain DE of the transistor TR are formed from the semiconductor pattern. The source SE and the drain DE extend in opposite directions from the channel AC in a cross-sectional view. FIG. 7 illustrates a portion of the signal line SCL formed from the semiconductor pattern. The signal line SCL is connected to the drain DR of the transistor 100PC.

The semiconductor pattern of the transistor TR includes at least one of polysilicon, amorphous silicon, or a metal oxide, but is not necessarily limited to any one as long as it has semiconducting properties.

The semiconductor pattern includes a plurality of regions divided according to a level of conductivity. In the semiconductor pattern, a region doped with a dopant or reduced with a metal oxide has a high conductivity and serves as source and drain electrodes of the transistor TR. A region with high conductivity in the semiconductor pattern corresponds to the source SE and the drain DE of the transistor TR. A region that is undoped or doped at a low concentration or has a low conductivity due to a non-reduced metal oxide corresponds to the channel AC (or active region) of the transistor TR.

The first insulating layer IOL1 covers the semiconductor pattern of the transistor TR and is disposed on the buffer layer BFL. The gate GT of the transistor TR is disposed on the first insulating layer IOL1. The gate GT overlaps the channel AC of the transistor TR. In an embodiment, the gate GT functions as a mask in a process of doping the semiconductor pattern of the transistor TR.

The gate GT includes at least one of titanium (Ti), silver (Ag), an alloy containing silver, molybdenum (Mo), an alloy containing molybdenum, aluminum (Al), an alloy containing aluminum, aluminum nitride (AIN), tungsten (W), tungsten nitride (WN), copper (Cu), indium tin oxide (ITO), or indium zinc oxide (IZO), etc., but is not particularly limited thereto.

The first insulating layer IOL1 includes an inorganic film. The first insulating layer IOL1 may be referred to as a first inorganic film. For example, the first insulating layer IOL1 is an inorganic film that includes at least one of aluminum oxide, titanium oxide, silicon oxide, silicon nitride, silicon oxynitride, zirconium oxide, or hafnium oxide. The first insulating layer IOL1 may have a single layer or a multilayer structure. In an embodiment, the first insulating layer IOL1 has a structure that includes a plurality of laminated inorganic films. When the first insulating layer IOL1 includes a plurality of laminated inorganic films, the plurality of laminated inorganic films are disposed directly below the inorganic film and may further include a buffer inorganic film that has a relatively high O content compared to an adjacent inorganic film. The buffer inorganic film of the first insulating layer IOL1 has physical properties similar to the buffer insulating layer of the first sensor insulating layer ISL-B described above.

In addition, in an embodiment, the first insulating layer IOL1 further includes an organic film in addition to the inorganic film. When the first insulating layer IOL1 includes a structure in which the inorganic film and the organic film are laminated, the first insulating layer IOL1 further includes a buffer inorganic film disposed between the inorganic film and the organic film that are adjacent to each other. For example, the buffer inorganic film has physical properties similar to those of the buffer insulating layer of the first sensor insulating layer ISL-B described above. For example, the buffer inorganic film includes a relatively high content of O and C elements compared to the adjacent inorganic film.

The second to fourth insulating layers IOL2, IOL3, and IOL4, which are described below, have a multilayer structure similar to that of the first insulating layer IOL1. Thus, the second to fourth insulating layers IOL2, IOL3, and IOL4, etc., have the above-described laminated multilayered insulating layer and, the multilayered buffer inorganic film.

The second insulating layer IOL2 is disposed on the first insulating layer IOL1 and covers the gate GT. The second insulating layer IOL2 commonly overlaps the pixels. The second insulating layer IOL2 includes an inorganic film. The second insulating layer IOL2 may also be referred to as a second inorganic film. For example, the second insulating layer IOL2 includes at least one of silicon oxide, silicon nitride, or silicon oxynitride. The second insulating layer IOL2 includes an inorganic layer and/or an organic layer and have a single-layer or a multilayer structure. In an embodiment, the second insulating layer IOL2 has a multilayer structure that includes a silicon oxide layer and a silicon nitride layer.

The third insulating layer IOL3 is disposed on the second insulating layer IOL2. The third insulating layer IOL3 includes an inorganic film. The third insulating layer IOL3 may be referred to as a third inorganic film. The third insulating layer IOL3 may have a single layer or multilayer structure. In an embodiment, the third insulating layer IOL3 has a multilayer structure that includes a silicon oxide layer and a silicon nitride layer.

The first connection electrode CNE1 is disposed on the third insulating layer IOL3. The first connection electrode CNE1 is connected to the signal line SCL through a first contact hole CH-1 that passes through the first, second, and third insulating layers IOL1, IOL2, and IOL3.

The fourth insulating layer IOL4 is disposed on the third insulating layer IOL3 and covers the first connection electrode CNE1. The fourth insulating layer IOL4 includes an inorganic film, and the fourth insulating layer IOL4 may also be referred to as a fourth inorganic film. In an embodiment, the fourth insulating layer IOL4 is a single-layered silicon oxide layer.

The fifth insulating layer OML1 is disposed on the fourth insulating layer IOL4. The fifth insulating layer OML1 includes an organic film. The fifth insulating layer OML1 may be referred to as a first organic film. The first organic film includes at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, or a perylene-based resin.

The second connection electrode CNE2 is disposed on the fifth insulating layer OML1. The second connection electrode CNE2 is connected to the first connection electrode CNE1 through a second contact hole CH-2 that passes through the fourth insulating layer IOL4 and the fifth insulating layer OML1.

The sixth insulating layer OML2 is disposed on the fifth insulating layer OML1 and covers the second connection electrode CNE2. The sixth insulating layer OML2 includes an organic film. The sixth insulating layer OML2 may be referred to as a second organic film. The second organic film includes at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, or a perylene-based resin.

In addition, the circuit layer DP-CL further includes a plurality of transistors and also signal lines electrically connected to the plurality of transistors. The signal lines are connected to the panel pads D-PD (see FIG. 5) of the non-display area NDA (see FIG. 5). In addition, the signal lines are connected to the sensing pads T-PD of the non-sensing area NAA-S (see FIG. 6).

The display element layer DP-ED is disposed on the circuit layer DP-CL. The display element layer DP-ED includes a pixel defining layer PDL and the light emitting element LD. The light emitting element LD includes a first electrode AE, an emission layer EL, and a second electrode CE.

The first electrode AE is disposed on the sixth insulating layer OML2. The first electrode AE is connected to the second connection electrode CNE2 through a third contact hole CH-3 that passes through the sixth insulating layer OML2. The first electrode AE is electrically connected to the drain DE of the transistor TR through the first and second connection electrodes CNE1 and CNE2.

The first electrode AE may be referred to as a pixel electrode. The first electrode AE is made of one of a metal, a metal alloy, or a conductive compound. The first electrode AE may be an anode or a cathode. The first electrode AE may be one of a transmissive electrode, a transflective electrode or a reflective electrode. When the first electrode AE is a transmissive electrode, the first electrode AE includes a transparent metal oxide, such as at least one of indium tin oxide (ITO), indium zinc oxide (IZO), zinc oxide (ZnO), or indium tin zinc oxide (ITZO), etc. When the first electrode AE is a transflective electrode or a reflective electrode, the first electrode AE includes at least one of Ag, Mg, Cu, Al, Pt, Pd, Au, Ni, Nd, Ir, Cr, Li, Ca, LiF/Ca, LiF/Al, Mo, Ti, or a compound or mixture thereof, such as a mixture of Ag and Mg. In an embodiment, the first electrode AE includes a reflective layer or transflective layer that is made of the above-described material, and a transparent conductive film that includes at least one of indium tin oxide (ITO), indium zinc oxide (IZO), zinc oxide (ZnO), or indium tin zinc oxide (ITZO). In an embodiment, the first electrode AE includes a three-layered structure of ITO/Ag/ITO, but embodiments are not necessarily limited thereto. For example, in some embodiments, the first electrode AE includes the above-described metal, a combination of two or more metals selected from the above-described metals, or an oxide of the above-described metals.

The pixel defining layer PDL is disposed on the sixth insulating layer OML2. In an embodiment, the pixel defining layer PDL is made of a polymer resin. For example, the pixel define layer PDL includes a polyacrylate-based resin or a polyimide-based resin. In addition, the pixel defining layer PDL further includes an inorganic material in addition to the polymer resin. The pixel defining layer PDL includes a light absorbing material or a black pigment or a black dye. The pixel defining layer PDL that includes a black pigment or a black dye is a black pixel defining layer. When the pixel defining layer PDL is formed, the black pigment or the black dye is used as a carbon black, but embodiments of the inventive concept are not necessarily limited thereto.

In an embodiment, the pixel define layer PDL is made of an inorganic material. For example, the pixel defining layer PDL includes an inorganic material such as at least one of silicon nitride, silicon oxide, or silicon oxynitride, etc.

A light emitting opening PX-OP that exposes a portion of the first electrode AE is formed in the pixel defining layer PDL. In the display module DM according to an embodiment, emission areas PXA are divided by the pixel defining layer PDL. The display module DM includes the emission areas PXA and a non-emission area NPXA, and the non-emission area NPXA overlaps the pixel defining layer PDL. A portion that corresponds to the first electrode AE exposed through the light emitting opening PX-OP may be defined as the emission area PXA.

A plurality of the light emitting opening PX-OP are provided. As will be described below, first to third light emitting elements of the pixel PX are disposed in the plurality of light emitting openings PX-OP, respectively.

In the light emitting element LD, the emission layer EL is disposed on the first electrode AE. In an embodiment, the emission layer EL emits light having at least one color of blue, red, or green. In an embodiment, the emission layer EL emits blue light throughout the display area DA (see FIG. 5).

The second electrode CE is disposed on the emission layer EL. The second electrode CE has an integrated shape and is commonly disposed on the plurality of pixels PX (see FIG. 5). The second electrode CE may be referred to as a common electrode. The second electrode CE may be a cathode or an anode. For example, when the first electrode AE is the anode, the second electrode CE is the cathode, and when the first electrode AE is the cathode, the second electrode CE is the anode.

The second electrode CE may be a transmissive electrode, a transflective electrode, or a reflective electrode. When the second electrode CE is a transmissive electrode, the second electrode CE includes a transparent metal oxide, such as at least one of indium tin oxide (ITO), indium zinc oxide (IZO), zinc oxide (ZnO), or indium tin zinc oxide (ITZO). In addition, the second electrode CE includes at least one of Ag, Mg, Cu, Al, Pt, Pd, Au, Ni, Nd, Ir, Cr, Li, Ca, LiF/Ca, LiF/Al, Mo, Ti, or W, or a compound or mixture thereof, such as a mixture of Ag and Mg.

In addition, in an embodiment, a hole control layer is disposed between the first electrode AE and the emission layer EL. The hole control layer includes a hole transport layer and a hole injection layer. An electron control layer is disposed between the emission layer EL and the second electrode CE. The electron control layer includes an electron transport layer and an electron injection layer. The hole control layer and the electron control layer are commonly formed in the plurality of pixels PX (see FIG. 5) using an open mask.

The encapsulation layer TFE is disposed on the display element layer DP-ED. The encapsulation layer TFE includes a first inorganic layer IL1, an organic layer OL, and a second inorganic layer IL2 that are sequentially laminated. However, the layers of the encapsulation layer TFE are not necessarily limited thereto.

The inorganic layers IL1 and IL2 protect the display element layer DP-ED from moisture and oxygen, and the organic layer OL protects the display element layer DP-ED from foreign substances such as dust particles. Each of the inorganic layers IL1 and IL2 includes at least one of silicon nitride, silicon oxynitride, silicon oxide, titanium oxide, or aluminum oxide. The organic layer OL includes an acrylic-based organic material. However, the types of materials that constitute the inorganic layers IL1 and IL2 and the organic layer OL are not necessarily limited thereto.

The input sensor ISP is disposed on the encapsulation layer TFE. As described with reference to FIG. 4, in an embodiment, the input sensor ISP includes a sensor insulating layer ISL and a sensor conductive layer MTL.

According to an embodiment, the display module DM includes an optical layer AF. In an embodiment, the optical layer AF is directly disposed on the third insulating layer ISL-T. However, embodiments are not necessarily limited thereto, and in an embodiment, an adhesive layer is further provided between the optical layer AF and the input sensor ISP (see FIG. 5).

FIG. 7 shows that the second sensor conductive layer MTL2 is connected to the first sensor conductive layer MTL1 through a contact hole CNT.

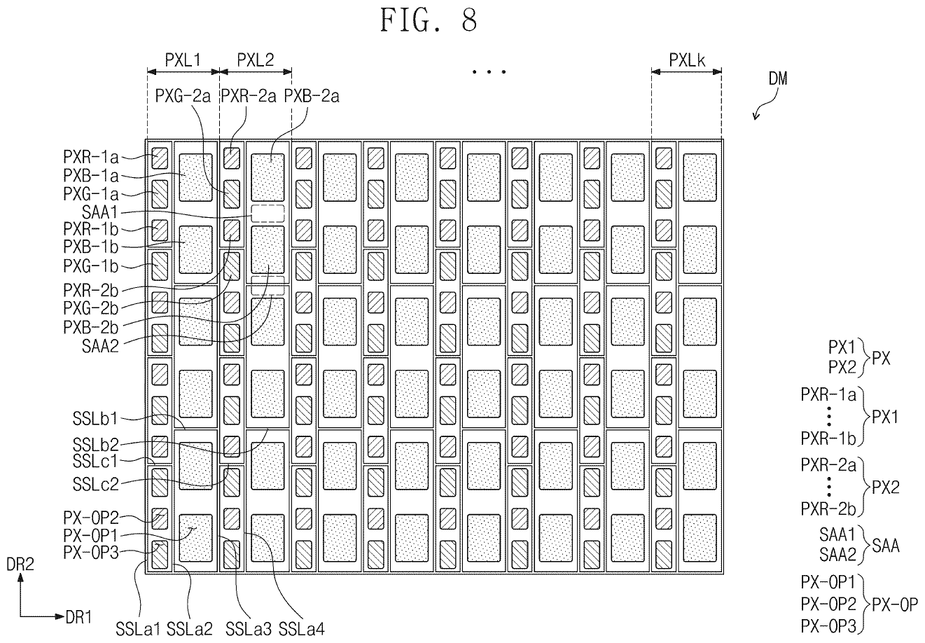

FIG. 8 is a plan view of a display module according to an embodiment of the inventive concept.

Referring to FIG. 8, in an embodiment, the plurality of pixels PX are arranged in the first direction DR1 to form a plurality of pixel rows and in the second direction DR2 to form a plurality of pixel columns PXL. The plurality of pixels PX form a matrix. For example, when number of the plurality of pixels PX is m×k, where m and k are each integers of 2 or more, the plurality of pixels PX are arranged in m pixel rows and k pixel columns. The k pixel columns are labeled PXL1, PXL2, . . . , PXLk.

Each of the pixel columns PXL include a plurality of pixels PX. The pixels PX of each pixel column PXL are arranged in the second direction DR2. For convenience of description, although only the leftmost first pixel column PXL1 and the second pixel column PXL2 adjacent to the first pixel column PXL1 are described, this description equally applies to an n-th pixel column PXLn, where n is an integer of 2 or more, and is not limited to any one embodiment.

The pixels PX of the first pixel column PXL1 may be defined as the first pixels PX1, and the pixels PX of the second pixel column PXL2 may be defined as the second pixels PX2. Each of the plurality of first and second pixels PX1 and PX2 includes first color light emitting elements PXB-1a, PXB-1b, PXB-2a, and PXB-2b, second color light emitting elements PXR-1a, PXR-1b, PXR-2a, and PXR-2b, and third color light emitting elements PXG-1a, PXG-1b, PXG-2a, and PXG-2b.

The first light emitting elements PXB-1a and PXB-1b of the first pixels PX1 are accommodated in the first light emitting openings PX-OP1. The second light emitting elements PXR-1a and PXR-1b of the first pixels PX1 are accommodated in the second light emitting openings PX-OP2. The third light emitting elements PXG-1a and PXG-1b of the first pixels PX1 are accommodated in the third light emitting openings PX-OP3. In addition, the first to third light emitting elements PXB-2a, PXB-2b, PXR-2a, PXR-2b, PXG-2a, and PXG-2b of the second pixels PX2 are also disposed in the light emitting openings PX-OP1, PX-OP2, and PX-OP3, respectively.

The first light emitting openings PX-OP1 are spaced apart from the second light emitting openings PX-OP2 in the first direction DR1. The first light emitting openings PX-OP1 are spaced apart from the third light emitting openings PX-OP3 in the first direction DR1. The second light emitting openings PX-OP2 are spaced apart from the third light emitting openings PX-OP3 in the second direction DR2.

The arrangement patterns of the first color light emitting elements PXB-1a, PXB-1b, PXB-2a, and PXB-2b, the second color light emitting elements PXR-1a, PXR-1b, PXR-2a, and PXR-2b, and the three color light emitting elements PXG-1a, PXG-1b, PXG-2a, and PXG-2b are the same as those of the first light emitting openings PX-OP1, the second light emitting openings PX-OP2, and the third light emitting openings PX-OP3, respectively. Hereinafter, the arrangement patterns of the first to third light emitting elements PXB-1a to PXG-2b of the first pixels PX1 and the second pixels PX2 will be described in detail.

The arrangements of the first color light emitting elements PXB-1a and PXB-1b, the second color light emitting elements PXR-1a and PXR-1b, and the third color light emitting elements PXG-1a and PXG-1b of the first pixels PX1 and the second pixels PX2 are the same. In addition, the arrangements of the first color light emitting elements PXB-1a, PXB-1b, PXB-2a, and PXB-2b, the second color light emitting elements PXR-1a, PXR-1b, PXR-2a, and PXR-2b, and the third color light emitting elements PXG-1a, PXG-1b, PXG-2a, and PXG-2b are the same. In an embodiment of the inventive concept, the first color, the second color, and the third color are blue, red, and green, respectively, but are not necessarily limited thereto.

The arrangement of the first to third color light emitting elements PXB-1a to PXG-2b in each pixel column PXL is substantially the same to reduce differences in visibility that distinguish the emission areas that correspond to each pixel between the adjacent pixel areas.

The first light emitting elements PXB-1a and PXB-1b of the first pixel PX1 are spaced apart from the second light emitting elements PXR-1a and PXR-1b of the first pixel PX1 in the first direction DR1. The first light emitting elements PXB-1a and PXB-1b of the first pixel PX1 are spaced apart from the third light emitting elements PXG-1a and PXG-1b of the first pixel PX1 in the first direction DR1. The second light emitting elements PXR-1a and PXR-1b of the first pixel PX1 are spaced apart from the third light emitting elements PXG-1a and PXG-1b of the first pixel PX1 in the second direction DR2.

As described above, the arrangement patterns of the light emitting elements PXB-2a, PXB-2b, PXR-2a, PXR-2b, PXG-2a, and PXG-2b of the second pixel PX2 are the same as those of the emission areas PXB-1a, PXB-1b, PXR-1a, PXR-1b, PXG-1a, and PXG-1b of the first pixel PX1. For example, the first light emitting elements PXB-2a and PXB-2b of the second pixel PX2 are spaced apart from the second light emitting elements PXR-2a and PXR-2b of the second pixel PX2 in the first direction DR1. The first light emitting elements PXB-2a and PXB-2b of the second pixel PX2 are spaced apart from the third light emitting elements PXG-2a and PXG-2b of the second pixel PX2 in the first direction DR1. The second light emitting elements PXR-2a and PXR-2b of the second pixel PX2 are spaced apart from the third light emitting elements PXG-2a and PXG-2b of the second pixel PX2 in the second direction DR2.

The second light emitting elements PXR-1a and PXR-1b of the first pixels PX1 and the third light emitting elements PXG-1a and PXG-1b of the first pixels PX1 are alternately arranged in the second direction DR2. The second light emitting elements PXR-2a and PXR-2b of the second pixels PX2 and the third light emitting elements PXG-2a and PXG-2b of the second pixels PX2 are alternately arranged in the second direction DR2.

Referring to the drawings, the first light emitting elements PXB-1a, PXB-1b, PXB-2a, and PXB-2b and the second light emitting elements PXR-1a and PXR-1b, PXR-2a, and PXR-2b, which have planar rectangular shapes with curved corners are illustrated. However, the shapes are not necessarily limited thereto, the planar shape of the light emitting elements may have a square, rectangular, or other polygonal shapes. For example, in an embodiment of the inventive concept, the corners of the shape of the light emitting elements may be defined not only by straight lines but also by curves.

The input sensor ISP described above using FIG. 6 includes a plurality of sensor lines SSL. In addition, the sensor conductive layer MTL described above using FIG. 7 includes a plurality of sensor lines SSL.

The plurality of sensor lines SSL are disposed on the pixel defining layer PDL (see FIG. 7). The sensor lines SSL are disposed between the plurality of pixels PX. The sensor lines SSL are disposed on the pixel defining layer PDL (see FIG. 7) that corresponds to the arrangement pattern of the light emitting elements. The sensor lines SSL extend in the first direction DR1 or the second direction DR2.

The sensor lines SSL include a plurality of first line parts SSLa, a plurality of second line parts SSLb, and a plurality of third line parts SSLc.

The plurality of first line parts SSLa pass between the first to third light emitting elements PXB-1a to PXG-2b. The first line parts SSLa extend in the second direction DR2. The first line parts SSLa include first line parts SSLa1 that are spaced apart from the second light emitting elements PXR-1a and PXR-1b and the third light emitting elements PXG-1a and PXG-1b in the first direction DR1. The first lines parts SSLa also include first line parts SSLa2 that pass between the first to third light emitting elements PXB-1a to PXG-1b of the first pixel PX1 in the first pixel column PXL1. In addition, the first line parts SSLa further include first line parts SSLa3 that pass between the first light emitting elements PXB-1a and PXB-1b of the first pixel PX1, and the second light emitting elements PXR-1a and PXR-1b and the third light emitting elements PXG-2a and PXG-2b of the second pixel PX2. In addition, the first line parts SSla include first line parts SSLa4 that pass between the first to third light emitting elements PXB-2a to PXG-2b of the first pixel PX2 in the second pixel column PXL2. This description applies to the pixels PX in the remaining pixel columns PXL.

The plurality of second line parts SSLb pass between the first light emitting elements PXB-1a, PXB-1b, PXB-2a, and PXB-2b adjacent to each other in the second direction DR2. The second line parts SSLb extend in the first direction DR1. The second line parts SSLb connect the first line parts SSLa adjacent in the first direction DR1. A first end and a second end of each of the second line parts SSLb is in contact with the adjacent first line parts SSLa.

The second line parts SSLb overlap the first light emitting elements PXB-1a, PXB-1b, PXB-2a, and PXB-2b in the second direction DR2. The second line parts SSLb do not overlap the second light emitting elements PXR-1a, PXR-1b, PXR-2a, and PXR-2b and the third light emitting elements PXG-1a, PXG-1b, PXG-2a, and PXG-2b in the second direction DR2.

At least one first light emitting element PXB-1a, PXB-1b, PXB-2a, or PXB-2b is disposed between the second line parts SSLb adjacent in the second direction DR2. For example, areas SAA located between the first light emitting elements PXB-1a, PXB-1b, PXB-2a, and PXB-2b include a first area SAA1 and a second area SSA2. The first area SAA1 is where no second line parts SSLb are disposed, or an area that does not overlap the second line parts SSLb. The second area SSA2 is where one of the second line parts SSLb is disposed or an area that overlaps the second line parts SSLb.

In the drawings, although two first light emitting elements PXB-1a, PXB-1b, PXB-2a, and PXB-2b are illustrated as being disposed between the adjacent second line parts SSLb, embodiments are not necessarily limited thereto. For example, in some embodiments, three or more first light emitting elements PXB-1a, PXB-1b, PXB-2a, and PXB-2b are provided.

The second line parts SSLb include first sub-line parts SSLb1 and second sub-line parts SSLb2. The first sub-line parts SSLb1 are disposed in the first pixel columns PXL1, and the second sub-line parts SSLb2 are disposed in the second pixel columns PXL2. For example, the first sub-line parts SSLb1 are disposed between the first light emitting elements PXB-1a and PXB-1b of the first pixel PX1, and the second sub-line parts SSLb2 may be disposed between the first light emitting elements PXB-2a and PXB-2b of the second pixel PX2. The first sub-line parts SSLb1 and the second sub-line parts SSLb2 overlap each other the first direction DR1. However, embodiments are not necessarily limited thereto, and in other embodiments, only a portion of the first sub-line parts SSLb1 and a portion of the second sub-line parts SSLb2 overlap each other the first direction DR1.

The plurality of third line parts SSLc pass between those second light emitting elements PXR-1a, PXR-1b, PXR-2a, and PXR-2b and those third light emitting elements PXG-1a, PXG-1b, PXG-2a, and PXG-2b that are adjacent in the second direction DR2. The third line parts SSLc extend in the first direction DR1. The third line parts SSLc connect the first line parts SSLa adjacent in the first direction DR1. A first end and a second end of each of the third line parts SSLc are in contact with the adjacent first line parts SSLa.

The third line parts SSLc overlap the second light emitting elements PXR-1a, PXR-1b, PXR-2a, and PXR-2b and the third light emitting elements PXG-1a, PXG-1b, PXG-2a, and PXG-2b in the second direction DR2. The third line parts SSLc do not overlap the first light emitting elements PXB-1a, PXB-1b, PXB-2a, and PXB-2b in the second direction DR2.

Some portions third line parts SSLc overlap the second line parts SSLb in the first direction DR1. Remaining portions of the third line parts SSLc do not overlap the second line parts SSLb in the first direction DR1.

At least one second light emitting element PXR-1a, PXR-1b, PXR-2a, or PXR-2b and at least one third light emitting element PXG-1a, PXG-1b, PXG-2a, or PXG-2b is disposed between the third line parts SSLc adjacent in the second direction DR2. The number of light emitting elements located between adjacent third line parts SSLc in the second direction DR2 is an odd number. The number of light emitting elements is one more than the number of other light emitting elements between the second line parts SSLb adjacent in the second direction DR2.

Referring to FIG. 8, in the first pixel column PXL1, two second light emitting elements PXR-1a and PXR-1b and one third light emitting element PXG-1a are disposed between some third line parts SSLc adjacent in the second direction DR2. In addition, one second light emitting element and two third light emitting elements PXG-1b are disposed between other third line parts SSLc adjacent in the second direction DR2.

A light emitting element group in which two second light emitting elements PXR-1a and PXR-1b and one third light emitting element PXG-1a are disposed between the third line parts SSLc adjacent in the second direction DR2 may be defined as a first light emitting element group, and a light emitting element group in which one second light emitting element and two third light emitting elements PXG-1b are disposed between the third line parts SSLc adjacent in the second direction DR2 may be defined as a second light emitting element group. A plurality of each of the first light emitting element group and the second light emitting element group are provided. The first light emitting element groups and the second light emitting element groups are alternately arranged in the second direction DR2. This arrangement similarly applies to the second pixel column PXL2 and other pixel columns PXL.

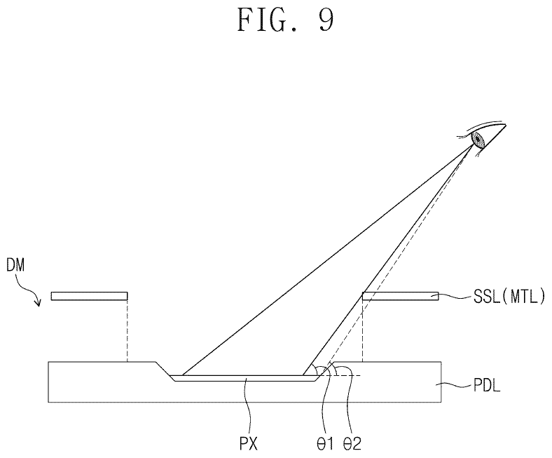

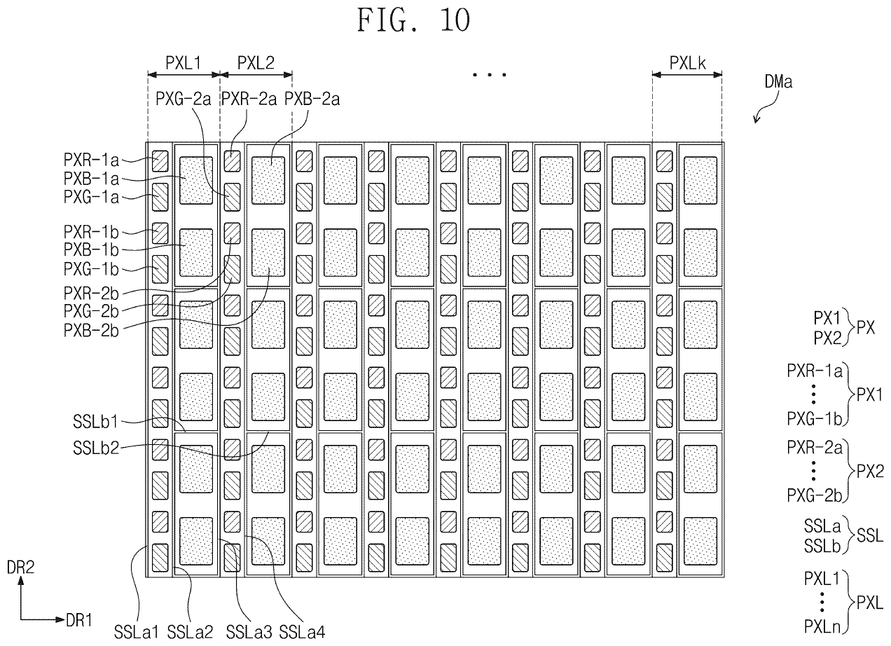

In the first light emitting element groups, the second light emitting elements PXR-1a, PXR-1b, PXR-2a, and PXR-2b are closer to the third line parts SSLc than the third light emitting elements PXG-1a, PXG-1b, PXG-2a, and PXG-2b. The second light emitting elements PXR-1a, PXR-1b, PXR-2a, and PXR-2b are adjacent to the third line parts SSLc, and thus, when the user looks in the second direction DR2, such as a vertical direction, the second light emitting elements PXR-1a, PXR-1b, PXR-2a, and PXR-2b are covered by the third line parts SSLc. See FIG. 9, which will be described below.

In the second light emitting element groups, the third light emitting elements PXG-1a, PXG-1b, PXG-2a, and PXG-2b are closer to the third line parts SSLc than the second light emitting elements PXR-1a, PXR-1b, PXR-2a, and PXR-2b.

The first light emitting element groups and the second light emitting element groups are alternately arranged in the second direction DR2, and thus, the total number of second light emitting elements PXR-1a, PXR-1b, PXR-2a, and PXR-2b and the total number of third light emitting elements PXG-1a, PXG-1b, PXG-2a, and PCG-2b are substantially the same. For example, the number of second light emitting elements PXR-1a, PXR-1b, PXR-2a, and PXR-2b and the third light emitting elements PXG-1a, PXG-1b, PXG-2a, PXG-2b of the light emitting elements of the third line part SSLc adjacent in one direction is the same.

As a result, when a user looks in a direction parallel to the second direction DR2, such as an upward direction, and when the user looks at the display device DD in a direction opposite to the second direction DR2, such as a downward direction, there is no difference in display quality. As a result, differences in display quality can be prevented from occurring when the user looks at the display device DD in the second direction DR2, such as a vertical direction.

Since the number of first to third light emitting elements PXG-1a to PXG-2b covered in the first direction DR1, such as left and right directions is the same, there is no difference in display quality of the display device DD when a user looks in the first direction DR1, such as a left or right direction.

The third line parts SSLc include third sub-line parts SSLc1 and fourth sub-line parts SSLc2. The third sub-line parts SSLc1 are disposed between the first pixel columns PX1 and PXL1, and the fourth sub-line parts SSLc2 are disposed between the second pixel columns PXL2. For example, the third sub-line parts SSLc1 are disposed between the second light emitting elements PXR-1a and PXR-1b and the third light emitting elements PXG1a and PXG-1b of the first pixel PX1, and the fourth sub-line parts SSLc2 are disposed between the second light emitting elements PXR-2a and PXR-2b and the third light emitting elements PXG-2a and PXG-2b of the second pixel PX2. The third sub-line parts SSLc1 and the fourth sub-line parts SSLc2 overlap each other in the first direction DR1. However, embodiments are not necessarily limited thereto, and in other embodiments, only a portion of the third sub-line parts SSLc1 and a portion of the fourth sub-line parts SSLc2 overlap each other in the first direction DR1.

According to an embodiment of the inventive concept, widths of the first to third line parts SSLa, SSLb, and SSLc are the same. However, embodiments are not necessarily limited thereto, and in other embodiments, widths of the second line parts SSLb and the third line parts SSLc differ from each other.

FIG. illustrates how a portion of a pixel is curved by a sensor line according to a direction in which a user looks. For convenience of description, only a portion of the display module DM is illustrated in FIG. 9.

Referring to FIG. 9, a portion of the pixel PX is covered by the sensor line SSL, depending on a direction or angle at which a user looks at the display device.

Referring to the drawing, when the user looks at the display device at a first angle θ1, the pixel PX is not covered by the sensor line SSL. When the user looks at the display device at a second angle θ2, the pixel PX is covered by the sensor line SSL. The second angle θ2 is greater than the first angle θ1.

The first angle θ1 and the second angle θ2 vary depending on the direction or angle at which the user looks at the display device. In addition, the first angle θ1 and the second angle θ2 vary depending on whether the covered portions correspond to the first light emitting elements PXB-1a, PXB-1b, PXB-2a, and PXB-2b (see FIG. 8), the second light emitting elements PXR-1a, PXR-1b, PXR-2a, and PXR-2b (see FIG. 8) or the third light emitting elements PXG-1a, PXG-1b, PXG-2a, and PXG-2b (see FIG. 8).

For the first light emitting elements PXB-1a, PXB-1b, PXB-2a, and PXB-2b (see FIG. 8), when compared to the second light emitting elements PXR-1a, PXR-1b, PXR-2a, and PXR-2b (see FIG. 8) and the third light emitting elements PXG-1a, PXG-1b, PXG-2a, and PXG-2b (see FIG. 8), a distance between the adjacent first light emitting elements PXB-1a, PXB-1b, PXB-2a, and PXB-2b is greater than that between each of the second light emitting elements PXR-1a, PXR-1b, PXR-2a, and PXR-2b (see FIG. 8) and each of the third light emitting elements PXG-1a, PXG-1b, PXG-2a, and PXG-2b (see FIG. 8). Thus, for the first light emitting elements PXB-1a, PXB-1b, PXB-2a, and PXB-2b (see FIG. 8), the second angle θ2 is about 60 degrees or more. For the second light emitting elements PXR-1a, PXR-1b, PXR-2a, and PXR-2b (see FIG. 8) and the third light emitting elements PXG-1a, PXG-1b, PXG-2a, and PXG-2b (see FIG. 8), the second angle θ2 is less than about 60 degrees.

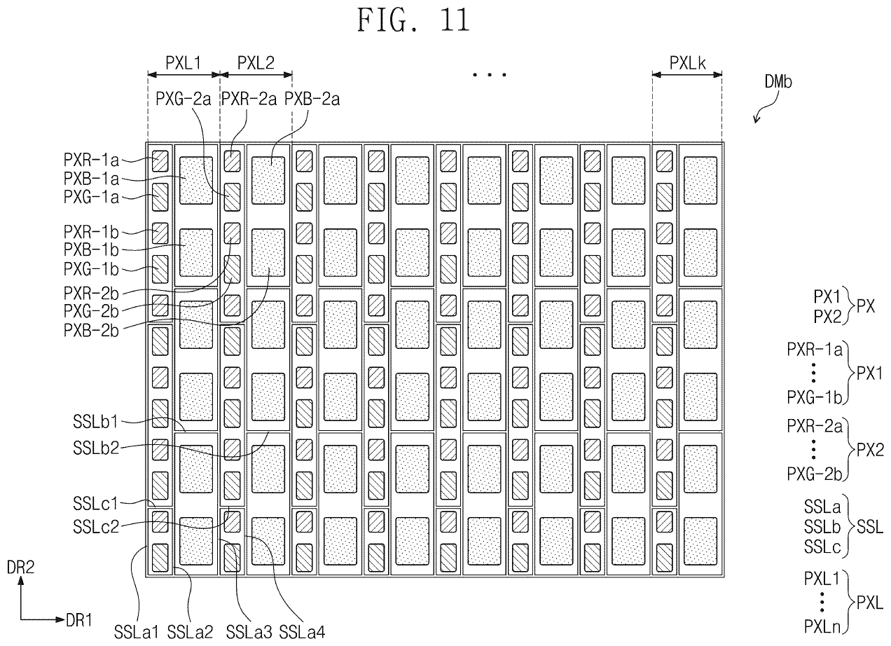

Thus, as described below using FIG. 10, the number of third line parts SSLc is less than the number of second line parts SSLb, or the third line parts SSLc are omitted to minimize or prevent the second light emitting elements PXR-1a, PXR-1b, PXR-2a, and PXR-2b and the third light emitting elements PXG-1a, PXG-1b, PXG-2a, and PXG-2b from being covered in the second direction DR2. As a result, compared to the first light emitting elements PXB-1a, PXB-1b, PXB-2a, and PXB-2b in the display device, covering the second and third light emitting elements PXR-1a to PXR-2b, PXG-1a to PXG-2b is minimized to increase the overall display quality of the display device.

FIGS. 10 to 15 are plan views of display modules DMa, DMb, DMc, DMd, DMe, DMf according to an embodiment of the inventive concept.

Hereinafter, in describing FIGS. 10 to 15, components similar to those described using FIG. 8 have the same or similar reference numerals, and repeated descriptions thereof may be omitted or summarized.

Referring to FIG. 10, in an embodiment, the third line parts SSLc are omitted from the plurality of sensor lines SSL. The third line parts SSLc are omitted to prevent the second light emitting elements PXR-1a, PXR-1b, PXR-2a, and PXR-2b and the third light emitting elements PXG-1a, PXG-1b, PXG-2a, and PXG-2b from being covered. As a result, there is no difference in display quality when the user looks at the display device in a direction parallel to the second direction DR2 and when the user looks at the display device in a direction opposite to the second direction DR2. As a result, differences in display quality can be prevented from occurring when the user looks at the display device in the second direction DR2.

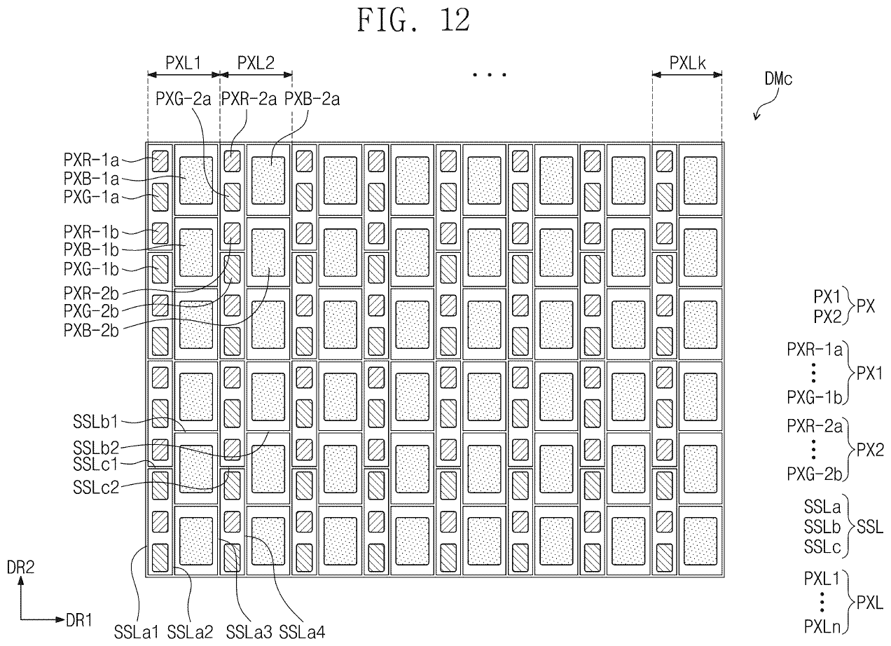

Referring to FIG. 11, in an embodiment, two second light emitting elements PXR-1a, PXR-1b, PXR-2a, and PXR-2b and three third light emitting elements PXG-1a, PXG-1b, PXG-2a, and PXG-2b are disposed between third line parts SSLc adjacent in the second direction DR2. The second light emitting elements PXR-1a, PXR-1b, PXR-2a, and PXR-2b and the third light emitting elements PXG-1a, PXG-1b, PXG-2a, and PXG-2b are alternately arranged in the second direction DR2.

In addition, three second light emitting elements PXR-1a, PXR-1b, PXR-2a, and PXR-2b and two third light emitting elements PXG1, PXG-1b, PXG-2a, and PXG-2b are disposed between other third line parts SSLc. The second light emitting elements PXR-1a, PXR-1b, PXR-2a, and PXR-2b and the third light emitting elements PXG-1a, PXG-1b, PXG-2a, and PXG-2b are alternately arranged in the second direction DR2.

A light emitting element group in which two second light emitting elements PXR-1a, PXR-1b, PXR-2a, and PXR-2b and three third light emitting element PXG-1a, PXG-1b, PXG-2a, and PXG-2b are disposed between the third line parts SSLc adjacent in the second direction DR2 may be defined as a first light emitting element group, and a light emitting element group in which three second light emitting elements PXR-1a, PXR-1b, PXR-2a, and PXR-2b and two third light emitting elements PXG-1a, PXG-1b, PXG-2a, and PXG-2b are disposed between the third line parts SSLc adjacent in the second direction DR2 may be defined as a second light emitting element group. The first light emitting element group and the second light emitting element group are alternately arranged in the second direction DR2.

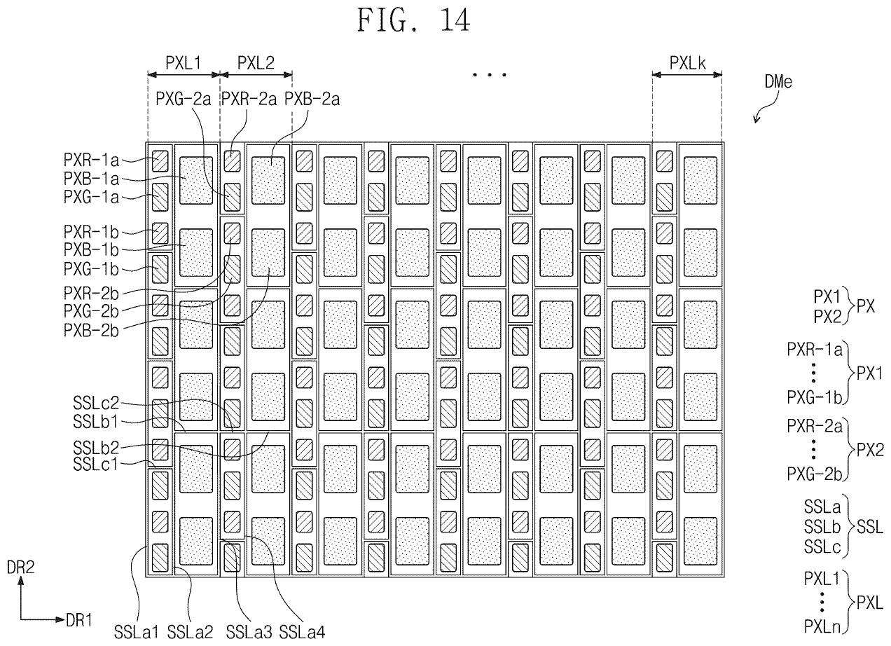

In the first light emitting element group, the second light emitting elements PXR-1a, PXR-1b, PXR-2a, and PXR-2b may be closer to the third line parts SSLc than the third light emitting elements PXG-1a, PXG-1b, PXG-2a, and PXG-2b. The second light emitting elements PXR-1a, PXR-1b, PXR-2a, and PXR-2b are adjacent to the third line parts SSLc, and thus, when the user looks in the second direction DR2, such as the vertical direction, the second light emitting elements PXR-1a, PXR-1b, PXR-2a, and PXR-2b are covered by the third line parts SSLc (see FIG. 13).

In the second light emitting element group, the third light emitting elements PXG-1a, PXG-1b, PXG-2a, and PXG-2b are closer to the third line parts SSLc than the second light emitting elements PXR-1a, PXR-1b, PXR-2a, and PXR-2b.

The first light emitting element group and the second light emitting element group are alternately arranged in the second direction DR2, and thus, the total number of second light emitting elements PXR-1a, PXR-1b, PXR-2a, and PXR-2b and the total number of third light emitting elements PXG-1a, PXG-1b, PXG-2a, and PCG-2b that are covered in the second direction DR2 are substantially the same. As a result, when the user looks in a direction parallel to the second direction DR2, such as an upward direction, and when the user looks in a direction opposite to the second direction DR2, such as a downward direction, there is no difference in display quality. As a result, differences in display quality can be prevented from occurring when the user looks at the display device in the second direction DR2, such as the vertical direction.

Since the number of first to third light emitting elements PXB-1a to PXG-2b covered in the first direction DR1, such as the left and right directions, is the same, there is no difference in display quality when the user looks in the first direction DR1, such as the left and right direction.

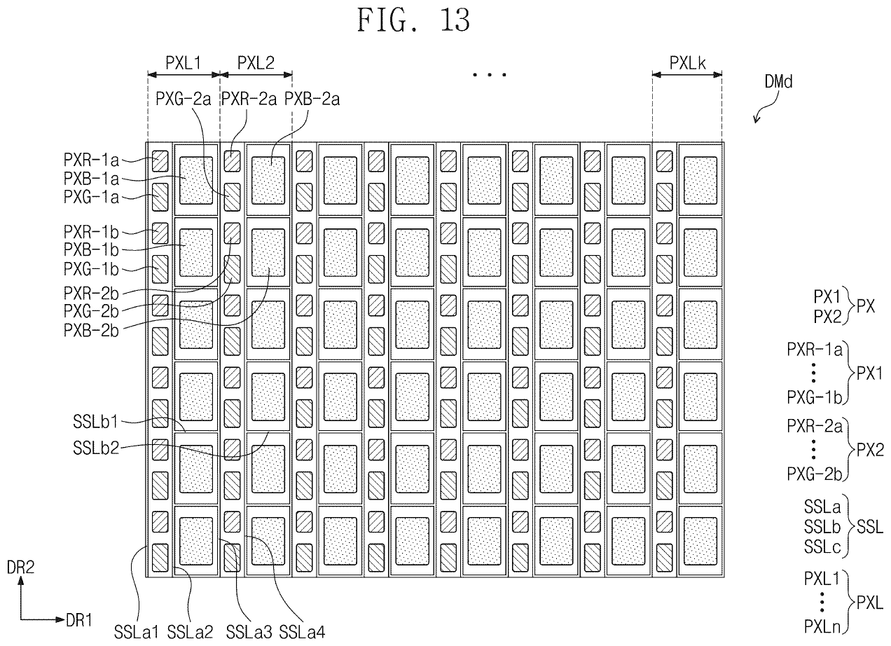

Referring to FIGS. 12 and 13, in an embodiment, one first light emitting element PXB-1a, PXB-1b, PXB-2a, or PXB-2b is disposed between the second line parts SSLb adjacent to each other in the second direction DR2. The first light emitting elements PXB-1a, PXB-1b, PXB-2a, and PXB-2b and the second line parts SSLb are alternately arranged in the second direction DR2. The number of second line parts SSLb increases, and thus, signals are easily transmitted through the sensor lines SSL.

According to an embodiment illustrated in FIG. 12, at least one second light emitting element PXR-1a, PXR-1b, PXR-2a, or PXR-2b and at least one third light emitting element PXG-1a, PXG-1b, PXG-2a, or PXG-2b is disposed between the third line parts SSLc adjacent in the second direction DR2.

According to an embodiment illustrated in FIG. 13, the third line parts SSLc are omitted from the plurality of sensor lines SSL. The third line parts SSLc are omitted to prevent the second light emitting elements PXR-1a, PXR-1b, PXR-2a, and PXR-2b and the third light emitting elements PXG-1a, PXG-1b, PXG-2a, and PXG-2b from being covered. As a result, there is no difference in display quality when the user looks at the display device in a direction parallel to the second direction DR2 and when the user looks at the display device in a direction opposite to the second direction DR2. As a result, differences in display quality can be prevented from occurring when the user looks at the display device in the second direction DR2.

In addition, even if the third line parts SSLc are omitted, the number of second line parts SSLb increases, and thus, signals can be easily transmitted through the sensor lines SSL.

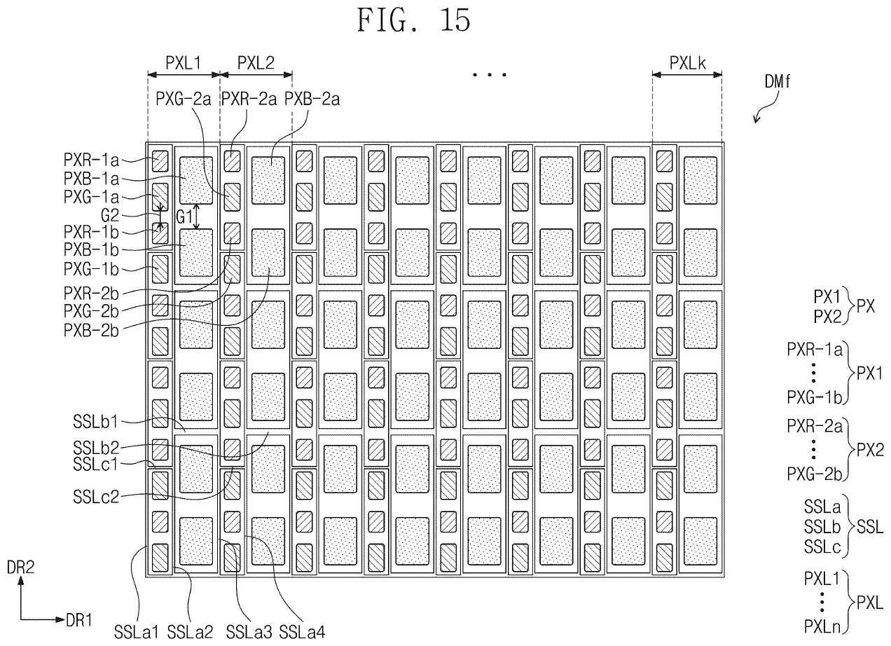

Referring to FIG. 14, in an embodiment, the third sub-line parts SSLc1 and the fourth sub-line parts SSLc2 do not overlap each other in the first direction DR1.

One second light emitting element PXR-1a, PXR-1b, PXR-2a, or PXR-2b and two third light emitting elements PXG-1a, PXG-1b, PXG-2a, and PXG-2b are disposed between some third sub-line parts SSLc1 and fourth sub-line parts SSLc2 adjacent in the second direction DR2. In addition, two second light emitting elements PXR-1a, PXR-1b, PXR-2a, and PXR-2b and one third light emitting element PXG-1a, PXG-1b, PXG-2a, or PXG-2b are disposed between the other third sub-line parts SSLc1 and fourth sub-line parts SSLc2.

A light emitting element group in which one second light emitting element PXR-1a, PXR-1b, PXR-2a, or PXR-2b and two third light emitting element PXG-1a, PXG-1b, PXG-2a, and PXG-2b are disposed between the third sub-line parts SSLc1 adjacent in the second direction DR2 may be defined as a first light emitting element group, and a light emitting element group in which two second light emitting elements PXR-1a, PXR-1b, PXR-2a, and PXR-2b and one third light emitting element PXG-1a, PXG-1b, PXG-2a, or PXG-2b are disposed between the third sub-line parts SSLcl adjacent in the second direction DR2 may be defined as a second light emitting element group. The first light emitting element group and the second light emitting element group are alternately arranged in the second direction DR2.

A light emitting element group in which one second light emitting element PXR-1a, PXR-1b, PXR-2a, or PXR-2b and two third light emitting element PXG-1a, PXG-1b, PXG-2a, and PXG-2b are disposed between the fourth sub-line parts SSLc adjacent in the second direction DR2 may be defined as a third light emitting element group, and a light emitting element group in which two second light emitting elements PXR-1a, PXR-1b, PXR-2a, and PXR-2b and one third light emitting element PXG-1a, PXG-1b, PXG-2a, or PXG-2b are disposed between the fourth sub-line parts SSLc2 adjacent in the second direction DR2 may be defined as a fourth light emitting element group. The third light emitting element group and the fourth light emitting element group are alternately arranged in the second direction DR2.

The first light emitting element group and the second light emitting element group partially overlap the third light emitting element group in the first direction DR1. In addition, the first light emitting element group and the second light emitting element group partially overlap the fourth light emitting element group in the first direction DR1.

In the first light emitting element group and the third light emitting element group, the second light emitting elements PXR-1a, PXR-1b, PXR-2a, and PXR-2b are closer to the third line parts SSLc than the third light emitting elements PXG-1a, PXG-1b, PXG-2a, and PXG-2b. The second light emitting elements PXR-1a, PXR-1b, PXR-2a, and PXR-2b are adjacent to the third sub-line parts SSLc1 or the fourth sub-line parts SSLc2, and thus, when viewed in the second direction DR2, such as a vertical direction, the second light emitting elements PXR-1a, PXR-1b, PXR-2a, and PXR-2b are covered by the third sub-line parts SSLc1 and the fourth sub-line parts SSLc2.

In the second light emitting element group and the fourth light emitting element group, the third light emitting elements PXG-1a, PXG-1b, PXG-2a, and PXG-2b are closer to the third sub-line parts SSLc1 and the fourth sub-line parts SSLc2 than the second light emitting elements PXR-1a, PXR-1b, PXR-2a, and PXR-2b.

The first light emitting element group and the second light emitting element group are alternately arranged in the second direction DR2, and the third light emitting element group and the fourth light emitting element group are alternately arranged in the second direction DR2, and thus, the total number of second light emitting elements PXR-1a, PXR-1b, PXR-2a, and PXR-2b and the total number of third light emitting elements PXG-1a, PXG-1b, PXG-2a, and PCG-2b that are covered in the second direction DR2 are substantially the same. For example, in the light emitting elements adjacent to each other at one side of the third sub-line parts SSLc1 and fourth sub-line parts SSLc2 within each of the first pixel column PXL1 or the second pixel column PXL2, the number of second light emitting elements PXR-1a, PXR-1b, PXR-2a, and PXR-2b and the number of third light emitting elements are the same.

As a result, when the user looks in a direction parallel to the second direction DR2, such as an upward direction, and when the user looks in a direction opposite to the second direction DR2, such as a downward direction, there is no difference in display quality. As a result, differences in display quality can be prevented from occurring when the user looks at the display device in the second direction DR2, such as the vertical direction.

Since the number of first to third light emitting elements PXB-1a to PXG-2b covered in the first direction DR1, such as the left and right directions, is the same, there is no difference in display quality when the user looks in the first direction DR1, such as the left and right directions.

In the drawings, although the first to fourth light emitting element groups are illustrated as including three light emitting elements PXR-1a to PXG-2b, embodiments are not necessarily limited thereto. For example, in some embodiments, the first to fourth light emitting element groups include an odd number of light emitting elements PXR-1a to PXG-2b. For example, I an embodiment, the light emitting element groups include 5 or 7 light emitting elements PXR-1a to PXG-2b.

In addition, in some embodiments, the number of light emitting elements PXR-1a to PXG-2b included in each light emitting element group differ from each other.

Referring to FIG. 15, in an embodiment, a distance between the first light emitting elements PXB-1a, PXB-1b, PXB-2a, and PXB-2b adjacent in the second direction DR2 is greater than that between each of the second light emitting elements and each of the third light emitting elements that are adjacent to each other in the second direction DR2. In addition, a distance between the first light emitting elements PXB-1a, PXB-1b, PXB-2a, and PXB-2b and the second line parts SSLb in the second direction DR2 is greater than or equal to that between each of the second light emitting elements PXR-1a, PXR-1b, PXR-2a, and PXR-2b or the third light emitting elements PXG-1a, PXG-1b, PXG-2a, and PXG-2b and the third line parts SSLc in the second direction DR2.

According to an embodiment of the inventive concept, a width of each of the second line parts SSLb is greater than or equal to that of each of the third line parts SSLc. Each of the second line parts SSLb has a wide width, and the sum of the widths of all sensor lines SSL is widened. As a result, the reliability of the signal transmission of the sensor line SSL is secured.

A display device according to an embodiment of the inventive concept provides a consistent display quality even when the user looks at the display panel in the vertical and horizontal directions.

A display device according to an embodiment of the inventive concept secures symmetry in the vertical direction in an arrangement relationship of the line parts of the sensor.

A display device according to an embodiment of the inventive concept secures symmetry in the left and right directions in the arrangement relationship of the line parts of the sensor.

It will be apparent to those skilled in the art that various modifications and deviations can be made in embodiments of the inventive concept. Thus, it is intended that embodiments of the inventive concept cover the modifications and deviations provided they come within the scope of the appended claims and their equivalents. Accordingly, the technical scope of embodiments of the inventive concept should not be limited to the contents described in the detailed description of the specification, but should be determined by the claims.

What is claimed is:

1. A display device, comprising:
a base layer;
a pixel defining layer disposed on the base layer and that includes a plurality of light emitting openings spaced apart from each other;
a plurality of pixels that include a plurality of first color light emitting elements, a plurality of second color light emitting elements, and a plurality of third color light emitting elements and disposed in the light emitting openings, wherein the first to third colors differ from each other; and
a sensor disposed on the pixel defining layer and spaced apart from the light emitting openings,
wherein the sensor comprises:
a plurality of first line parts that extend in a second direction and passes between the first to third color light emitting elements; and
a plurality of second line parts that extend in a first direction that crosses the second direction and pass between two adjacent first color light emitting elements of the plurality of first color light emitting elements and connects the two adjacent first line parts of the plurality of first line parts to each other,
wherein a first end and a second end of each of the second line parts are in contact with the adjacent first line parts, respectively.

2. The display device of claim 1, wherein the sensor comprises a plurality of third line parts that extend in the first direction and pass between two adjacent light emitting elements of the plurality of second color light emitting elements and the plurality of third color light emitting elements and connect the two adjacent first line parts of the plurality of first line parts to each other.

3. The display device of claim 1, wherein areas between the first color light emitting elements comprise:
a first area on which one of the second line parts is disposed; and
a second area that does not overlap the second line parts.

4. The display device of claim 1, wherein the second line parts and the first color light emitting elements are alternately arranged in the second direction.

5. The display device of claim 2, wherein
the first color light emitting elements and the second color light emitting elements are alternately arranged in the second direction, and
a number of light emitting elements between the adjacent third line parts is an odd number.

6. The display device of claim 5, wherein the number of light emitting elements between the adjacent third line parts is three.

7. The display device of claim 5, wherein some light emitting elements of the plurality of second color light emitting elements and the plurality of third color light emitting elements between the adjacent third line parts of the plurality of third line parts include one more than a number of other light emitting elements.

8. The display device of claim 2, wherein
the plurality of light emitting openings comprise a plurality of first light emitting openings, a plurality of second light emitting openings respectively spaced apart from the first light emitting openings in the first direction, and a plurality of third light emitting openings respectively spaced apart from the first light emitting openings in the first direction and respectively spaced apart from the second light emitting openings in the second direction, wherein the plurality of first color light emitting elements are respectively disposed in the first light emitting openings, the plurality of second color light emitting elements are respectively disposed in the second light emitting openings, and the plurality of third color light emitting elements are respectively disposed in the third light emitting openings,
a first distance between the first light emitting openings adjacent in the second direction is greater than a second distance between each of the second light emitting openings and each of the third light emitting openings that are adjacent in the second direction, and
a width of each of the second line parts is greater than or equal to that of each of third line parts.

9. The display device of claim 2, wherein
some portions of the third line parts overlap the second line part in the first direction, and
remaining portions of the first line parts do not overlap the second line part in the first direction.

10. The display device of claim 1, further comprising
an encapsulation layer disposed on the pixel defining layer and that covers the first to third color light emitting elements,
wherein the sensor comprises:
a first insulating layer disposed on the encapsulation layer;
a first conductive layer disposed on the first insulating layer;
a second insulating layer disposed on the first conductive layer;
a second conductive layer disposed on the second insulating layer,
wherein the first line parts and the second line parts are disposed on the first conductive layer or the second conductive layer.

11. A display device, comprising:
first pixel columns and second pixel columns that are arranged in a first direction and include a plurality of pixels arranged in a second direction that crosses the first direction; and
a sensor disposed between the pixels,
wherein each of the pixels comprises:
a first color light emitting element;
a second color light emitting element spaced apart from the first color light emitting element in the first direction; and
a third color light emitting element spaced apart from the first color light emitting element in the first direction and spaced apart from the second color light emitting element in the second direction,
wherein the sensor comprises:
a plurality of first line parts that extend in the second direction and pass between the first to third color light emitting elements; and
a plurality of second line parts that extend in the first direction and connect two adjacent first line parts of the plurality of first line parts to each other,
wherein the plurality of second line parts are disposed between adjacent first color light emitting elements of the plurality of first line parts in the second direction.

12. The display device of claim 11, wherein the plurality of second line parts comprise:
first sub-line parts disposed between the first pixel columns; and
second sub-line parts disposed between the second pixel columns,
wherein the first sub-line parts and the second sub-line parts overlap each other in the first direction.

13. The display device of claim 11, wherein areas between the first color light emitting elements comprise:
a first area on which one of the plurality of second line parts is disposed; and
a second area that does not overlap the second line parts.

14. The display device of claim 11, wherein the second line parts and the plurality of first color light emitting elements are alternately arranged in the second direction.

15. The display device of claim 11, wherein the sensor comprises:
a plurality of third line parts that extend in the first direction and pass between two adjacent light emitting elements of the plurality of second color light emitting elements and the plurality of third color light emitting elements and connect two adjacent first line parts of the plurality of first line parts to each other.

16. The display device of claim 15, wherein a number of the plurality of second color light emitting elements and a number of the plurality of third color light emitting elements adjacent in one direction in each of the third line parts within each of the first pixel columns or the second pixel columns are a same.

17. The display device of claim 15, wherein the plurality of first color light emitting elements and the plurality of second color light emitting elements are alternately arranged in the second direction,
a number of light emitting elements between adjacent third line parts of the plurality of third line parts is an odd number, and
some light emitting elements of the plurality of second color light emitting elements and the plurality of third color light emitting elements between the adjacent third line parts include one more than a number of other light emitting elements.

18. The display device of claim 15, wherein some portions of the third line parts overlaps the second line part in the first direction, and remaining portions of the first line parts do not overlap the second line part in the first direction.

19. The display device of claim 15,
wherein the second line parts comprise:
first sub-line parts disposed between the first pixel columns; and
second sub-line parts disposed between the second pixel columns,
wherein the third line parts comprise:
third sub-line parts disposed between the first pixel columns; and
fourth sub-line parts disposed between the second pixel columns,
wherein the first sub-line parts and the second sub-line parts overlap each other in the first direction, and
the third sub-line parts and the fourth sub-line parts overlap each other in the first direction.

20. The display device of claim 15, wherein a width of each of the second line parts is greater than or equal to that of each of the third line parts.
